(19) United States
(12) Patent Application Publication
(10) Pub. No.: US 2025/0218950 A1
(43) Pub. Date: Jul. 3, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jongsoon PARK, Suwon-si (KR); Hyonwook RA, Suwon-si (KR); Sangduk PARK, Suwon-si (KR); Keunhee BAI, Suwon-si (KR); Sughyun SUNG, Suwon-si (KR); Jinwook LEE, Suwon-si (KR)

(73) Assignee: SAMSUNG ELECTRONICS CO., LTD., Suwon-si (KR)

(21) Appl. No.: 18/788,918

(22) Filed: Jul. 30, 2024

(30) Foreign Application Priority Data
Dec. 28, 2023 (KR) 10-2023-0194300

(51) Int. Cl. H01L 23/535; H01L 21/768; H01L 23/528; H01L 29/06; H01L 29/417; H01L 29/423; H01L 29/66; H01L 29/775; H01L 29/786

(52) U.S. Cl. CPC H01L 23/535; H01L 21/76804; H01L 21/76805; H01L 21/76843; H01L 21/76895; H01L 23/5283; H01L 23/5286; H10D 30/014; H10D 30/43; H10D 30/6729; H10D 30/6735; H10D 30/6757; H10D 62/121; H10D 64/017

(57) ABSTRACT

A semiconductor device may include: a first source/drain pattern; a first active contact on the first source/drain pattern; a power line above the first active contact; and a first via contact connecting the first active contact to the power line, wherein the first via contact comprises a first side surface and a second side surface, which are opposite to each other in a first direction, the first side surface is inclined at a first angle to a top surface of the first active contact, the second side surface is inclined at a second angle to the top surface of the first active contact, and the first angle is an obtuse angle, and the second angle is an acute angle.

### CROSS-REFERENCE TO RELATED APPLICATION

This application claims priority under 35 U.S.C. § 119 to Korean Patent Application No. 10-2023-0194300, filed on Dec. 28, 2023, in the Korean Intellectual Property Office, the disclosure of which is incorporated herein in its entirety by reference.

### BACKGROUND

Embodiments of the disclosure relate to semiconductor devices and methods of fabricating the same, and in particular, to semiconductor devices including field effect transistors and methods of fabricating the same.

A semiconductor device includes an integrated circuit including metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY

Embodiments of the disclosure provide a semiconductor device with improved electrical and reliability characteristics.

The embodiments also provide a method of fabricating a semiconductor device with improved electrical and reliability characteristics.

According to one or more embodiments, a semiconductor device may include: a first source/drain pattern; a first active contact on the first source/drain pattern; a power line above the first active contact; and a first via contact connecting the first active contact to the power line, wherein the first via contact includes a first side surface and a second side surface, which are opposite to each other in a first direction, the first side surface is inclined at a first angle to a top surface of the first active contact, the second side surface is inclined at a second angle to the top surface of the first active contact, and the first angle is an obtuse angle, and the second angle is an acute angle.

According to one or more embodiments, a semiconductor device may include: a first source/drain pattern and a second source/drain pattern; a first active contact on the first source/drain pattern and a second active contact on the second source/drain pattern; a first power line and a second power line spaced apart from each other in a first direction; a first via contact connecting the first active contact to the first power line and including a first side surface; and a second via contact connecting the second active contact to the second power line and including a second side surface, wherein the first side surface has a first slope, and the second side surface has a second slope, and one of the first slope and the second slope is a positive slope, and the other is a negative slope.

According to one or more embodiments, a semiconductor device may include: a first source/drain pattern and a second source/drain pattern on a substrate; a channel pattern connected to the first source/drain pattern and the second source/drain pattern, the channel pattern including a plurality of semiconductor patterns, which are stacked to be spaced apart from each other; a first active contact and a second active contact coupled to the first source/drain pattern and the second source/drain pattern, respectively; a first power line and a second power line spaced apart from each other in a first direction; and a first via contact and a second via contact on bottom surfaces of the first power line and the second power line, respectively, wherein the first via contact connects the first power line to the first active contact, the second via contact connects the second power line to the second active contact, and a distance between the first active contact and the second active contact increases as a distance from a top surface of the substrate in a vertical direction increases.

According to one or more embodiments, a semiconductor device may include: a substrate; a first source/drain pattern on the substrate; and a first contact structure through which the first source/drain pattern is connected to a first metal line connecting the first contact structure to a first voltage source or a first circuit element; wherein a vertical center line of a top surface of the first contact structure is offset from a vertical center line of a bottom surface of the first contact structure.

### BRIEF DESCRIPTION OF DRAWINGS

FIGS. 1 to 3 are conceptual diagrams illustrating logic cells of a semiconductor device, according to one or more embodiments.

FIG. 4 is a plan view illustrating a semiconductor device, according to one or more embodiments.

FIGS. 5A to 5E are sectional views taken along lines A-A′, B-B′, C-C′, D-D′, and E-E′ of FIG. 4, respectively.

FIGS. 6A and 6B are enlarged sectional views illustrating portions ‘M’ and

‘N’ of FIG. 5C, respectively.

FIGS. 7A to 12C are sectional views illustrating a method of fabricating a semiconductor device, according to one or more embodiments.

FIGS. 13A and 13B are sectional views illustrating a method of fabricating the semiconductor device of FIG. 5E.

FIGS. 14A to 15C are sectional views illustrating a method of fabricating the semiconductor device of FIG. 5C.

FIG. 16 is a sectional view, which is taken along a line C-C′ of FIG. 4 to illustrate a semiconductor device according to one or more embodiments.

FIG. 17 is an enlarged sectional view illustrating a portion ‘O’ of FIG. 16.

### DETAILED DESCRIPTION

The embodiments described herein are non-limiting example embodiments, and thus, the disclosure is not limited thereto and may be realized in various other forms. Each of the embodiments provided herein is not excluded from being associated with one or more features of another example or another embodiment also provided herein or not provided herein but consistent with the disclosure. For example, even if matters described in a specific example or embodiment are not described in a different example or embodiment, the matters may be understood as being related to or combinable with the different example or embodiment, unless otherwise mentioned in descriptions thereof.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Herein, when a term “same” or “equal” is used to compare a dimension of two or more elements, the term may cover a “substantially same” or “substantially equal” dimension

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

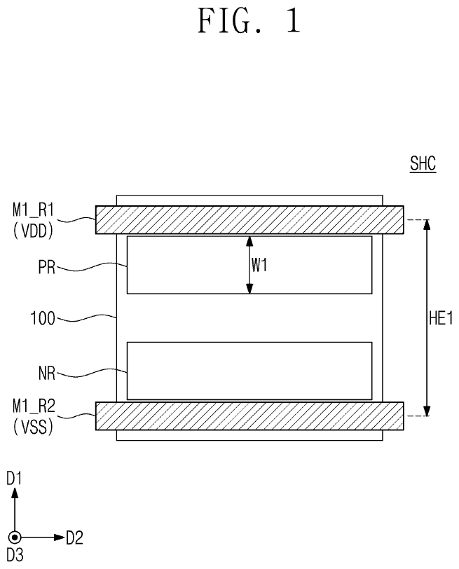

FIGS. 1 to 3 are conceptual diagrams illustrating logic cells of a semiconductor device according to one or more embodiments.

Referring to FIG. 1, a single height cell SHC may be provided. A first power line M1_R1 and a second power line M1_R2 may be provided on a substrate 100. The first power line M1_R1 may be a conduction path, to which a drain voltage VDD (e.g., a power voltage) is provided. The second power line M1_R2 may be a conduction path, to which a source voltage VSS (e.g., a ground voltage) is provided.

The single height cell SHC may be defined between the first power line M1_R1 and the second power line M1_R2. The single height cell SHC may include one p-type metal-oxide-semiconductor field-effect transistor (PMOSFET) region PR and one n-type metal-oxide-semiconductor field-effect transistor (NMOSFET) region NR. That is, the single height cell SHC may have a CMOS structure provided between the first power line M1_R1 and the second power line M1_R2.

Each of the PMOSFET region PR and the NMOSFET region NR may have a first width WII in a first direction D1. A length of the single height cell SHC in the first direction D1 may be defined as a first height HE1. The first height HE1 may be substantially equal to a distance (e.g., a pitch) between the first power line M1_R1 and the second power line M1_R2.

The single height cell SHC may constitute a single logic cell. In the present specification, the logic cell may mean a logic device (e.g., AND, OR, XOR, XNOR, inverter, and so forth), which is configured to execute a specific function. For example, the logic cell may include transistors constituting the logic device and interconnection lines connecting the transistors to each other.

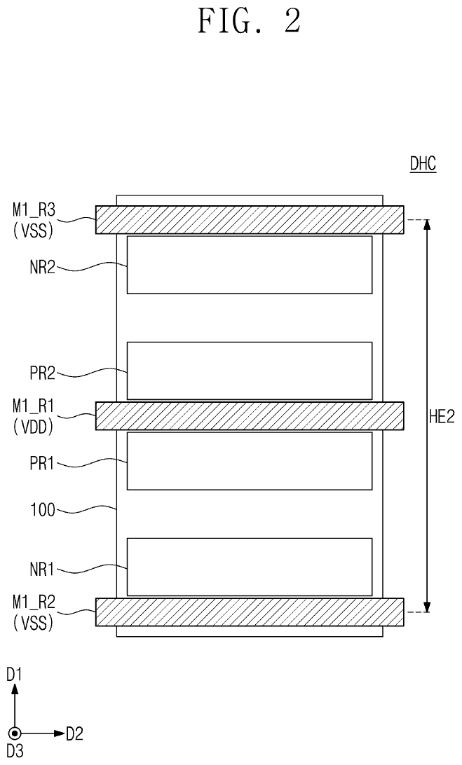

Referring to FIG. 2, a double height cell DHC may be provided. A first power line M1_R1, a second power line M1_R2, and a third power line M1_R3 may be provided on the substrate 100. The first power line M1_R1 may be disposed between the second power line M1_R2 and the third power line M1_R3 in the first direction D1. The third power line M1_R3 may be a conduction path, to which the source voltage VSS is provided.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first PMOSFET region PR1 and the second PMOSFET region PR2 may be adjacent to the first power line M1_R1. When viewed in a plan view, the first power line M1_R1 may be disposed between the first PMOSFET region PR1 and the second PMOSFET region PR2.

A length of the double height cell DHC in the first direction D1 may be defined as a second height HE2. The second height HE2 may be about two times the first height HE1 of FIG. 1. The first PMOSFET region PR1 and the second PMOSFET region PR2 of the double height cell DHC may be combined to serve as a single PMOSFET region.

Thus, a channel size of the PMOS transistor of the double height cell DHC may be larger than a channel size of the PMOS transistor of the single height cell SHC of FIG. 1. For example, the channel size of the PMOS transistor of the double height cell DHC may be about two times the channel size of the PMOS transistor of the single height cell SHC. In this case, the double height cell DHC may be operated at a higher speed than the single height cell SHC. In one or more embodiments, the double height cell DHC shown in FIG. 2 may be defined as a multi-height cell. Although not shown, the multi-height cell may include a triple height cell whose cell height is about three times that of the single height cell SHC.

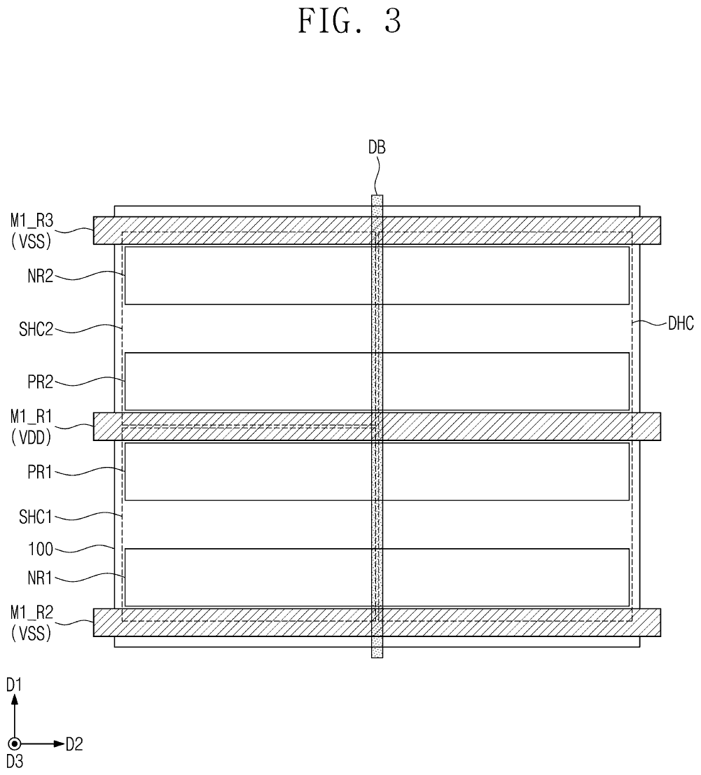

Referring to FIG. 3, a first single height cell SHC1, a second single height cell SHC2, and a double height cell DHC may be two-dimensionally arranged on the substrate 100. The first single height cell SHC1 may be disposed between the first power line M1_R1 and the second power line M1_R2. The second single height cell SHC2 may be disposed between the first power line M1_R1 and the third power line M1_R3. The second single height cell SHC2 may be adjacent to the first single height cell SHC1 in the first direction D1.

The double height cell DHC may be disposed between the second power line M1_R2 and the third power line M1_R3. The double height cell DHC may be adjacent to the first single height cell SHC1 and the second single height cell SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first single height cell SHC1 and the second single height cell SHC2 by the division structure DB.

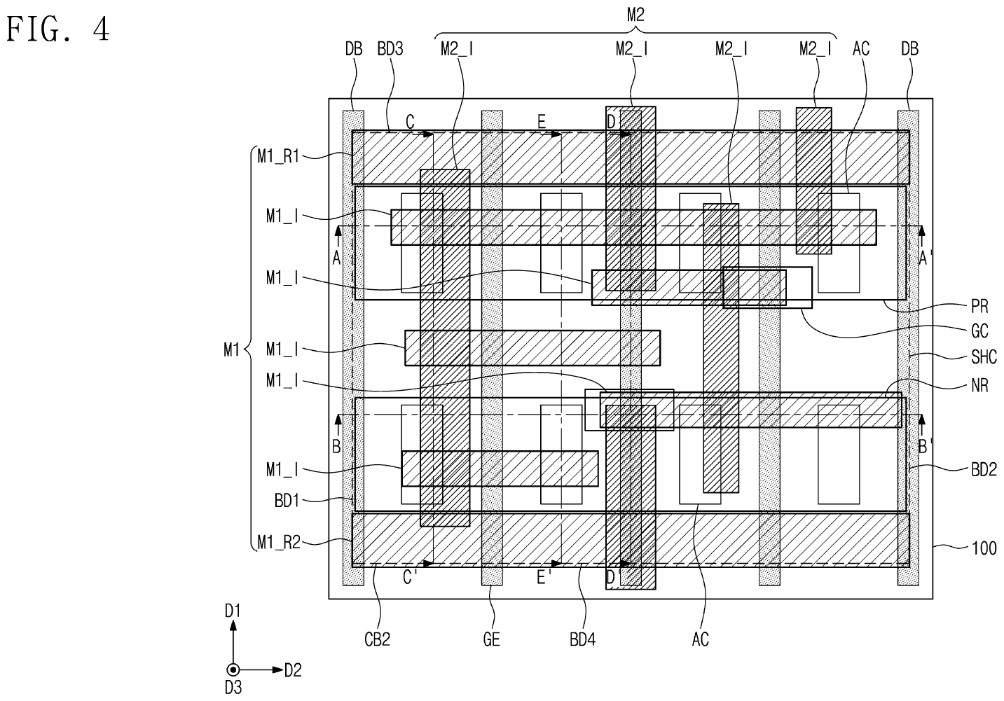

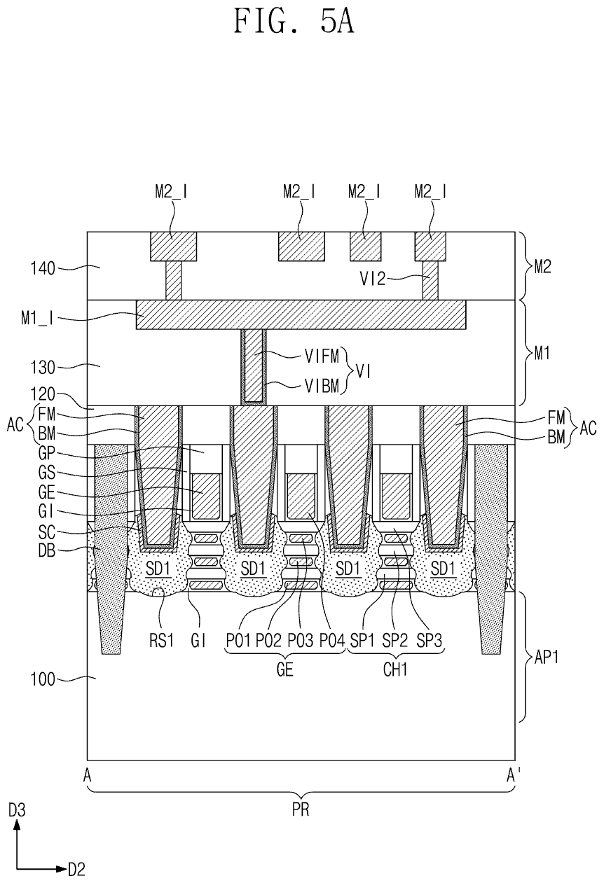

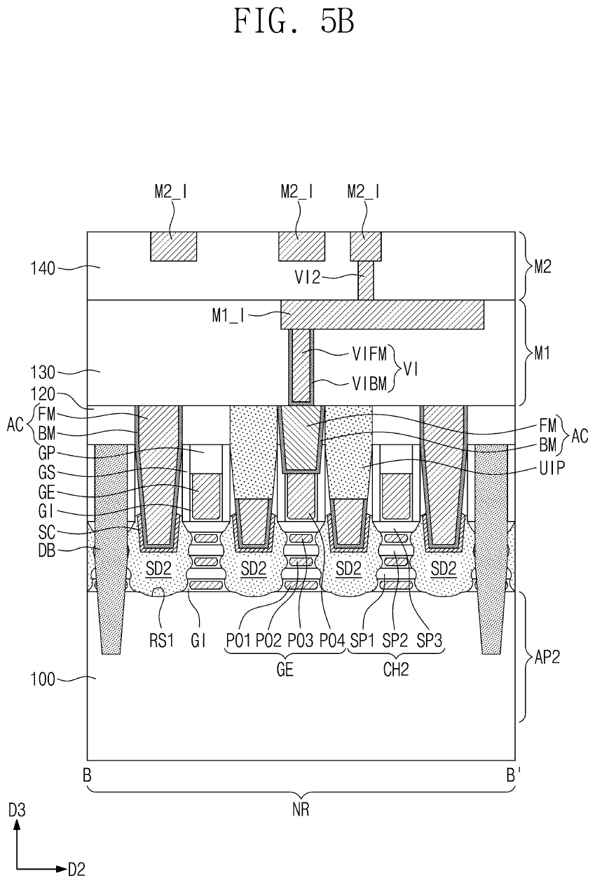

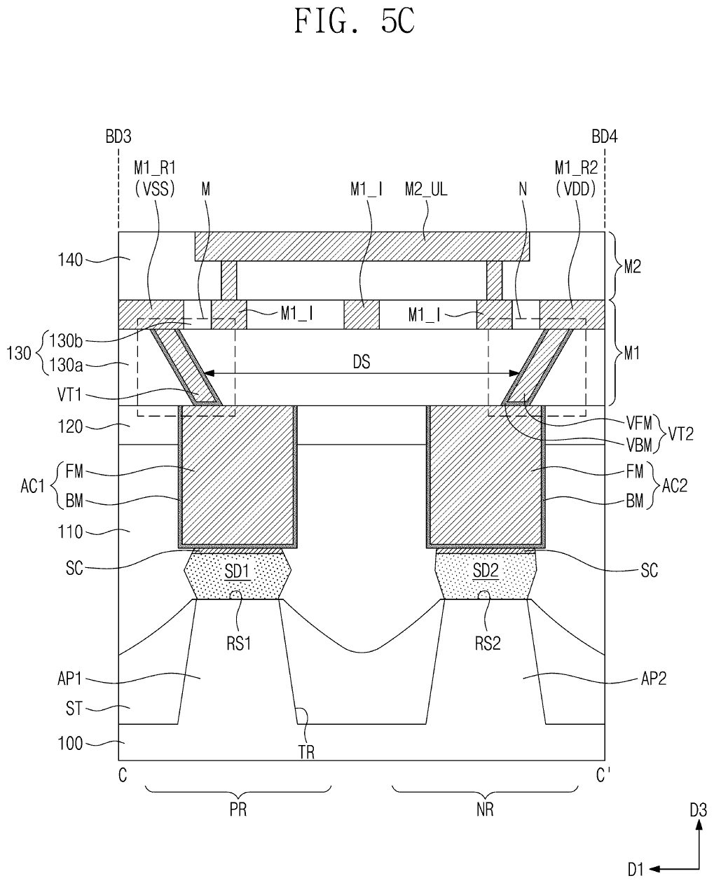

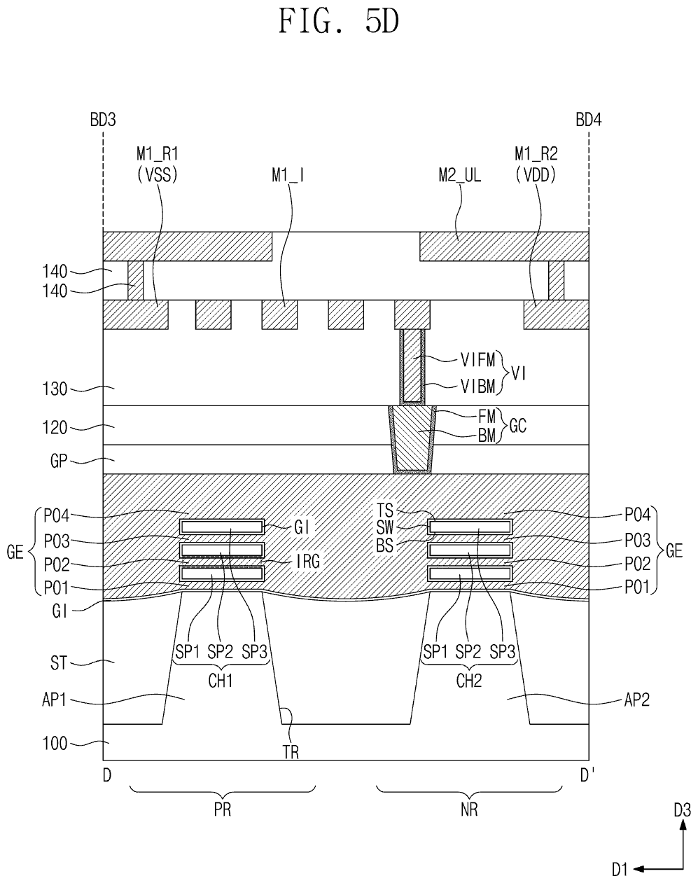

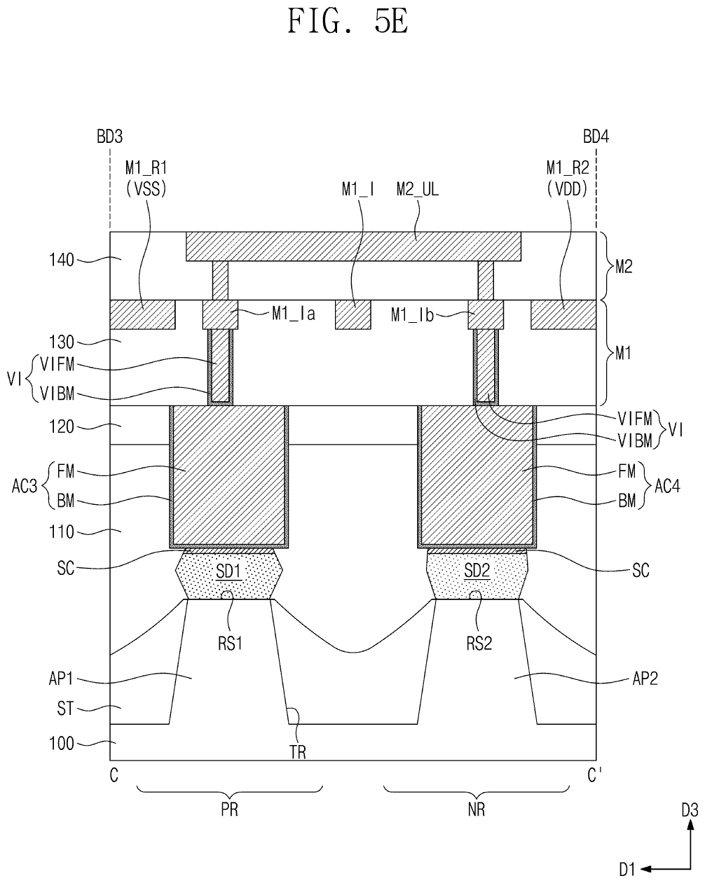

FIG. 4 is a plan view illustrating a semiconductor device according to one or more embodiments. FIGS. 5A to 5E are sectional views taken along lines A-A′, B-B′, C-C′, D-D′, and E-E′ of FIG. 4, respectively. The semiconductor device of FIGS. 4 and 5A to 5E may be a concrete example of the single height cell SHC of FIG. 1.

Referring to FIGS. 4 and 5A to 5E, the single height cell SHC may be provided on the substrate 100. Logic transistors constituting a logic circuit may be disposed on the single height cell SHC. The substrate 100 may be a semiconductor substrate that is formed of or includes silicon, germanium, silicon germanium, a compound semiconductor material, or the like. In one or more embodiments, the substrate 100 may be a silicon wafer.

A first active pattern AP1 and a second active pattern AP2 may be defined by a trench TR, which is formed in an upper portion of the substrate 100. The first active pattern AP1 may be provided on the PMOSFET region PR, and the second active pattern AP2 may be provided on the NMOSFET region NR. The first active pattern AP1 and the second active pattern AP2 may be extended in the second direction D2. Each of the first active pattern AP1 and the second active pattern AP2 may be a vertically-protruding portion of the substrate 100.

A device isolation layer ST may be provided on the substrate 100. The device isolation layer ST may be provided to fill the trench TR. The device isolation layer ST may include a silicon oxide layer. The device isolation layer ST may not cover first channel pattern CH1 and the second channel pattern CH2, which will be described below.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may be formed of or include at least one of silicon (Si), germanium (Ge), and silicon germanium (SiGe). For example, each of the first to third semiconductor patterns SP1, SP2, and SP3 may be formed of or include crystalline silicon. In one or more embodiments, the first to third semiconductor patterns SP1, SP2, and SP3 may be stacked nanosheets.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first source/drain patterns SD1 and the second source/drain patterns SD2 may be epitaxial patterns, which are formed by a selective epitaxial growth (SEG) process. In one or more embodiments, each of the first source/drain patterns SD1 and the second source/drain patterns SD2 may have a top surface that is higher than a top surface of the third semiconductor pattern SP3. In one or more other embodiments, a top surface of at least one of the first source/drain patterns SD1 and the second source/drain patterns SD2 may be located at substantially the same level as the top surface of the third semiconductor pattern SP3.

In one or more embodiments, the first source/drain patterns SD1 may be formed of or include a semiconductor material (e.g., SiGe) whose lattice constant is greater than that of a semiconductor material of the substrate 100. In this case, the pair of the first source/drain patterns SD1 may exert a compressive stress on the first channel patterns CH1 therebetween. The second source/drain patterns SD2 may be formed of or include the same semiconductor element (e.g., Si) as the substrate 100. In this case, the pair of the second source/drain patterns SD2 may exert a tensile stress on the second channel patterns CH2 therebetween.

A side surface of each of the first source/drain patterns SD1 and the second source/drain patterns SD2 may have an uneven or embossing shape, as shown in FIGS. 5A and 5B. For example, the side surface of each of first source/drain patterns SD1 and the second source/drain patterns SD2 may have a wavy profile. The side surface of each of the first source/drain patterns SD1 and the second source/drain patterns SD2 may protrude toward first to third portions PO1, PO2, and PO3 of a gate electrode GE to be described below.

Gate electrodes GE may be provided to cross the first channel pattern CH1 and the second channel pattern CH2 and to extend in the first direction D1. The gate electrodes GE may be arranged at a first pitch in the second direction D2. Each of the gate electrodes GE may be vertically overlapped with the first channel pattern CH1 and the second channel pattern CH2.

The gate electrode GE may include a first portion PO1 interposed between the active pattern AP1 or AP2 and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Referring to FIG. 5D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround the channel pattern.

Referring back to FIGS. 4 and 5A to 5E, a pair of gate spacers GS may be respectively disposed on opposite side surfaces of the fourth portion PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be substantially coplanar with a top surface of a first interlayer insulating layer 110, which will be described below. In one or more embodiments, the gate spacers GS may be formed of or include at least one of silicon carbon nitride (e.g., SiCN), silicon carbon oxynitride (e.g., SiCON), and silicon nitride (e.g., SiN). In one or more other embodiment, the gate spacers GS may be provided to have a multi-layered structure, which includes at least two different materials selected from silicon carbon nitride (e.g., SiCN), silicon carbon oxynitride (e.g., SiCON), and silicon nitride (e.g., SiN).

A gate capping pattern GP may be provided on the gate electrode GE. The gate capping pattern GP may be extended along the gate electrode GE and in the first direction D1. The gate capping pattern GP may be formed of or include a material having an etch selectivity with respect to the first interlayer insulating layer 110 and a second interlayer insulating layer 120, which will be described below. The gate capping pattern GP may be formed of or include at least one of silicon oxynitride (e.g., SiON), silicon carbon nitride (e.g., SiCN), silicon carbon oxynitride (e.g., SiCON), and silicon nitride (e.g., SiN).

A gate insulating layer GI may be interposed between the gate electrode GE and the first channel pattern CH1 and between the gate electrode GE and the second channel pattern CH2. The gate insulating layer GI may be formed on the top surface TS, the bottom surface BS, and the side surfaces SW of each of the first to third semiconductor patterns SP1, SP2, and SP3. The gate insulating layer GI may also be formed on a top surface of the device isolation layer ST placed below the gate electrode GE.

In one or more embodiments, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Referring back to FIGS. 4 and 5A to 5E, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first portion PO) 1 to third portion PO3 of the gate electrode GE may include the first metal pattern or the work-function metal.

The first metal pattern may include a metal nitride layer. For example, the first metal pattern may include a layer that includes at least one metallic material, which is selected from the group consisting of titanium (Ti), tantalum (Ta), aluminum (Al), tungsten (W) and molybdenum (Mo), and nitrogen (N). In one or more other embodiments, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). For example, the third portion PO3 of the gate electrode GE may include the first metal pattern and the second metal pattern on the first metal pattern.

A first interlayer insulating layer 110 may be provided on the substrate 100. The first interlayer insulating layer 110 may be formed on the gate spacers GS and the first source/drain patterns SD1 and the second source/drain patterns SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 and the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110 to 140 may include a silicon oxide layer. The third interlayer insulating layer 130 may be formed of or include tetraethyl orthosilicate (TEOS).

The single height cell SHC may have a first border BD1 and a second border BD2, which are opposite to each other in the second direction D2. The first source/drain patterns SD1 and the second source/drain patterns SD2 may be extended in the first direction D1. The single height cell SHC may have a third border BD3 and a fourth border BD4, which are opposite to each other in the first direction D1. The third border BD3 and the fourth border BD4 may be extended in the second direction D2.

A pair of division structures DB, which are opposite to each other in the second direction D2, may be provided at both sides of each of the first single height cell SHC1 and the second single height cell SHC2. For example, the pair of the division structures DB may be respectively provided on the first border BD1 and the second border BD2 of the single height cell SHC. The division structure DB may be extended in the first direction D1 to be parallel to the gate electrodes GE. A pitch between the division structure DB and the gate electrode GE adjacent thereto may be equal to the first pitch.

The division structure DB may be provided to penetrate the first insulating layer 110 and the second interlayer insulating layer 120 and may be extended into the first active pattern AP1 and the second active pattern AP2. The division structure DB may be provided to penetrate an upper portion of each of the first active pattern AP1 and the second active pattern AP2. The division structure DB may electrically separate an active region of the single height cell SHC from an active region of a neighboring cell.

Active contacts AC may be provided to penetrate the first insulating layer 110 and the second interlayer insulating layer 120 to be electrically connected to the first source/drain patterns SD1 and the second source/drain patterns SD2, respectively. A pair of the active contacts AC may be respectively provided at both sides of the gate electrode GE. When viewed in a plan view, the active contact AC may be a bar-shaped pattern that is extended in the first direction D1. A width of the active contact AC in the first direction D1 may be smaller than a width of the gate electrode GE in the first direction D1.

The active contact AC may be a self-aligned contact. For example, the active contact AC may be formed by a self-alignment process using the gate capping pattern GP and the gate spacer GS. For example, the active contact AC may be formed on at least a portion of the side surface of the gate spacer GS. Although not shown, the active contact AC may also be formed on a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, and cobalt silicide.

Gate contacts GC may be provided to penetrate the second interlayer insulating layer 120 and the gate capping pattern GP to be electrically connected to the gate electrodes GE, respectively. When viewed in a plan view, the gate contacts GC may be overlapped with the PMOSFET and NMOSFET regions PR and NR, respectively. For example, the gate contact GC may be provided on the first active pattern AP1 (e.g., see FIG. 5D).

In one or more embodiments, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. For example, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring therebetween.

Each of the active and gate contacts AC and GC may include a conductive pattern FM and a barrier pattern BM on the conductive pattern FM. For example, the conductive pattern FM may be formed of or include at least one of metallic materials (e.g., aluminum, copper, tungsten, molybdenum, and cobalt). The barrier pattern BM may be provided on side and bottom surfaces of the conductive pattern FM. In one or more embodiments, the barrier pattern BM may include a metal layer and a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CON), and platinum nitride (PtN).

A first metal layer M1 may be provided in the third interlayer insulating layer 130. For example, the first metal layer M1 may include the first power line M1_R1, the second power line M1_R2, and first single interconnection lines M1_I, which may all be interconnection lines herein. The interconnection lines M1_R1, M1_R2, and M1_I of the first metal layer M1 may be extended in the second direction D2 and parallel to each other.

The first power line M1_R1 and the second power line M1_R2 may be respectively provided on the third and fourth borders BD3 and BD4 of the single height cell SHC. The first power line M1_R1 may be extended along the third border BD3 and in the second direction D2. The second power line M1_R2 may be extended along the fourth border BD4 and in the second direction D2.

The first single interconnection lines M1_I of the first metal layer M1 may be disposed between the first power line M1_R1 and the second power line M1_R2. The first single interconnection lines M1_I of the first metal layer M1 may be arranged at a second pitch in the first direction D1. The second pitch may be smaller than the first pitch. A linewidth of each of the first single interconnection lines M1_I may be smaller than a linewidth of each of the first power line M1_R1 and the second power line M1_R2.

The first metal layer M1 may further include first vias VI and via contacts VT. The first vias VI and the via contacts VT may be respectively provided below the interconnection lines M1_R1, M1_R2, and M1_I of the first metal layer M1. The active contact AC and the interconnection lines of the first metal layer M1 may be electrically connected to each other through the first via VI or the via contacts VT. The gate contact GC and the interconnection lines of the first metal layer M1 may be electrically connected to each other through the first via VI or the via contacts VT.

The interconnection lines of the first metal layer M1 may be formed by a different process from that for the first via VI and the via contacts VT. For example, the interconnection lines of the first metal layer M1 and the first via VI may be independently formed by respective single damascene processes. The semiconductor device according to the present embodiment may be fabricated using a sub-20 nm process.

A second metal layer M2 may be provided in the fourth interlayer insulating layer 140. The second metal layer M2 may include a plurality of upper interconnection lines M2_UL provided in the fourth interlayer insulating layer 140. Each of the upper interconnection lines M2_UL of the second metal layer M2 may be a line- or bar-shaped pattern that is extended in the first direction D1. For example, the upper interconnection lines M2_UL may be extended in the first direction D1 and parallel to each other.

The interconnection lines of the first metal layer M1 may be formed of or include a conductive material that is the same as or different from those of the second metal layer M2. For example, the interconnection lines of the first metal layer M1 and the second metal layer M2 may be formed of or include at least one of metallic materials (e.g., aluminum, copper, tungsten, ruthenium, molybdenum, and cobalt). A plurality of metal layers (e.g., M3, M4, M5, and so forth) may be additionally stacked on the fourth interlayer insulating layer 140. Each of the stacked metal layers may include interconnection lines, which are used as routing paths between cells.

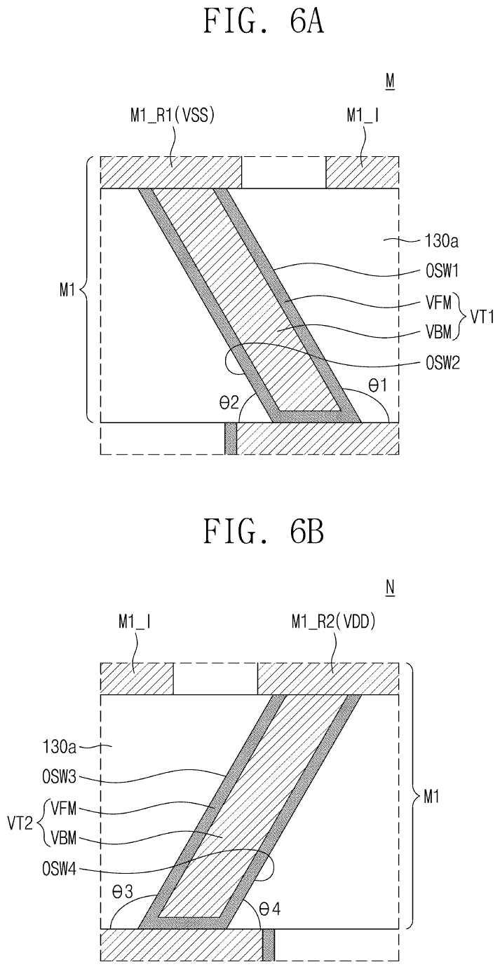

FIGS. 6A and 6B are enlarged sectional views illustrating portions ‘M’ and ‘N’ of FIG. 5C, respectively. The via contact VT and the first via VI will be described in more detail with reference to FIGS. 6A and 6B.

Referring to FIG. 6A, a first via contact VT1 may electrically connect a first active contact AC1 to the first power line M1_R1 on the first active contact AC1. A top surface of the first via contact VT1 may be in direct contact with a bottom surface of the first power line M1_R1. A bottom surface of the first via contact VT1 may be in direct contact with a top surface of the first active contact AC1.

The first via contact VT1 may include a first side surface OSW1 and a second side surface OSW2. The first side surface OSW1 and the second side surface OSW2 may face each other in the first direction D1. The top surface of the first active contact AC1 may be parallel to the first direction D1. The first side surface OSW1 may be inclined at a first angle θ1 to the top surface of the first active contact AC1. The second side surface OSW2 may be inclined at a second angle θ2 to the top surface of the first active contact AC1. The first angle θ1 may be an obtuse angle, and the second angle θ2 may be an acute angle. For example, the first angle θ1 may range from 100° to 150°. The second angle θ2 may range from 30° to 80°.

A vertical center line of the top surface of the first via contact VT1 may be offset from a vertical center line of the bottom surface of the first via contact VT1 in the first direction D1. The first via contact VT1 may have a tilting shape in the first direction D1. This is because the first active contact AC1 and the first power line M1_R1 are not placed on the same vertical line. When viewed in a plan view, the first active contact AC1 (AC) may be spaced apart from the first power line M1_R1 in the first direction D1 (e.g., see FIG. 4).

A width of the first via contact VT1 in the first direction D1 may be substantially constant regardless of the position in the vertical direction D3. Alternatively, the width of the first via contact VT1 in the first direction D1 may increase, as a distance from the top surface of the first active contact AC1 in the vertical direction D3 increases.

The first via contact VT1 may include a via conductive pattern VFM and a via barrier pattern VBM. The via barrier pattern VBM may be provided on the via conductive pattern VFM. The via barrier pattern VBM may be formed on side and bottom surfaces of the via conductive pattern VFM. The via barrier pattern VBM may be in direct contact with the top surface of the first active contact AC1.

The via barrier pattern VBM may include a metal layer and a metal nitride layer. For example, the via barrier pattern VBM may be formed of or include at least one of titanium, tantalum, tungsten, nickel, cobalt, platinum, titanium nitride (TiN), tantalum nitride (TaN), tungsten nitride (WN), nickel nitride (NiN), cobalt nitride (CON), and platinum nitride (PtN). For example, the via conductive pattern VFM may be formed of or include at least one of metallic materials (e.g., aluminum, copper, tungsten, molybdenum, ruthenium, and cobalt).

Referring to FIGS. 5C, 5E and 6A, a pair of the first source/drain patterns SD1, which are adjacent to each other in the second direction D2, may be connected to the first power line M1_R1 and a first single interconnection line M1_Ia, respectively. The first single interconnection line M1_Ia may be provided on the same vertical line as the first active contact AC1. The first via contact VT1 may be provided on the first source/drain pattern SD1 connected to the first power line M1_R1, and the first via VI may be provided on the first source/drain pattern SD1 connected to the first single interconnection line M1_Ia. The first via VI may be provided to vertically connect the first single interconnection line M1_Ia to a third active contact AC3 on the first source/drain pattern SD1. Thus, the first via contact VT1, which is at an angle to both of the first direction D1 and the third direction D3, and the first via VI, which is extended in the vertical direction D3, may be provided on the respective active patterns AC1 and AC3, or the respective source/drain patterns SD1.

Referring to FIG. 6B, a second via contact VT2 may electrically connect a second active contact AC2 to the second power line M1_R2 on the second active contact AC2. A top surface of the second via contact VT2 may be in direct contact with a bottom surface of the second power line M1_R2. A bottom surface of the second via contact VT2 may be in direct contact with a top surface of the second active contact AC2.

The second via contact VT2 may include a third side surface OSW3 and a fourth side surface OSW4. The third side surface OSW3 and the fourth side surface OSW4 may be opposite to each other in the first direction D1. The top surface of the second active contact AC2 may be parallel to the first direction D1. The third side surface OSW3 may be inclined at a third angle θ3 to the top surface of the second active contact AC2. The fourth side surface OSW4 may be inclined at a fourth angle θ4 to the top surface of the second active contact AC2. The third angle θ3 may be an obtuse angle, and the fourth angle θ4 may be an acute angle. For example, the third angle θ3 may range from 100° to 150°. The fourth angle θ4 may range from 30° to 80°.

A vertical center line of the top surface of the second via contact VT2 may be offset from a vertical center line of the bottom surface of the second via contact VT2 in the first direction D1. The second via contact VT2 may have a tilting shape in the first direction D1. A width of the second via contact VT2 in the first direction D1 may be substantially constant regardless of the position in the vertical direction D3. Alternatively, the width of the second via contact VT2 in the first direction D1 may increase, as a distance from the top surface of the first active contact AC1 in the vertical direction D3 increases.

The second via contact VT2 may include the via conductive pattern VFM and the via barrier pattern VBM. The via conductive pattern VFM and the via barrier pattern VBM of the second via contact VT2 may be provided to have substantially the same features as the via conductive pattern VFM and the via barrier pattern VBM of the first via contact VT1.

Referring to FIGS. 5C, 5E and 6B, a pair of the second source/drain patterns SD2, which are adjacent to each other in the second direction D2, may be connected to the second power line M1_R2 and a second single interconnection line M1_Ib, respectively. The second single interconnection line M1_Ib may be provided on the same vertical line as the second active contact AC2. The second via contact VT2 may be provided on the second source/drain pattern SD2 connected to the second power line M1_R2, and the first via VI may be provided on the second source/drain pattern SD2 connected to the second single interconnection line M1_Ib. The first via VI may be provided to vertically connect the second single interconnection line M1_Ib to a fourth active contact AC4 on the second source/drain pattern SD2. Thus, the second via contact VT2, which is at an angle to both of the first direction D1 and the third direction D3, and the first via VI, which is extended in the vertical direction D3, may be provided on the respective active patterns AC2 and AC4, or the respective source/drain patterns SD2.

A width of the first active contact AC1 in the first direction D1 may be substantially equal to a width of the third active contact AC3 in the first direction D1. A width of the second active contact AC2 in the first direction D1 may be substantially equal to a width of the fourth active contact AC4 in the first direction D1. All of the first to fourth active contacts AC1, AC2, AC3, and AC4 may have the same width in the first direction D1. All of the widths of the active contacts AC1, AC2, AC3, and AC4 on the substrate 100 may be the same.

Referring to FIGS. 5C, 6A, and 6B, the first via contact VT1 may electrically connect the first source/drain pattern SD1 to the source voltage VSS. The second via contact VT2 may electrically connect the second source/drain pattern SD2 to the drain voltage VDD. The first via contact VT1 and the second via contact VT2 may be connected to the source/drain patterns SD1 and SD2 containing different impurities from each other.

The first side surface OSW1 and the third side surface OSW3 may be opposite to each other in the first direction D1. The first side surface OSW1 and the third side surface OSW3 may be opposite to each other in the first direction D1. The first side surface OSW1 and the third side surface OSW3 may be side surfaces which are inclined at an obtuse angle to a top surface of each of the first active contact AC1 and the second active contact AC2.

The first side surface OSW1 may have a first slope. The third side surface OSW3 may have a second slope. One of the first slope and the second slope may be positive, and the other may be negative. For example, the first side surface OSW1 may have a negative slope, and the third side surface OSW3 may have a positive slope. Here, the normal of the first side surface OSW1 may have a positive slope, and the normal of the third side surface OSW3 may have a negative slope.

A first distance DS may be defined as the shortest distance between the first side surface OSW1 and the third side surface OSW3, which is measured in the first direction D1 at a specific level. The first distance DS may increase as a distance from a top surface of the substrate 100 in the vertical direction D3 increases. The first distance DS may increase as a distance from the top surfaces of the first active contact AC1 and the second active contact AC2 in the vertical direction D3 increases.

According to one or more embodiments, a via contact connecting an active contact to a power line may be provided to be inclined at an angle to both of the vertical direction D3 and the first direction D1. The active contact and the power line, which are spaced apart from each other in the first direction D1, may be directly connected to each other through the via contact. In this case, the via contact may have opposite side surfaces, which are inclined at obtuse and acute angles, respectively, with respect to the top surface of the active contact. Since the via contact is formed to have a tilted shape, the active contacts may be formed to have the same width, and this may make it possible to simplify the process of fabricating the semiconductor device.

Furthermore, since there is no need to extend the active contact in the first direction D1, it may be possible to prevent the active contact from being in contact with the side surface of the source/drain pattern. As a result, it may be possible to improve the electrical and reliability characteristics of the semiconductor device.

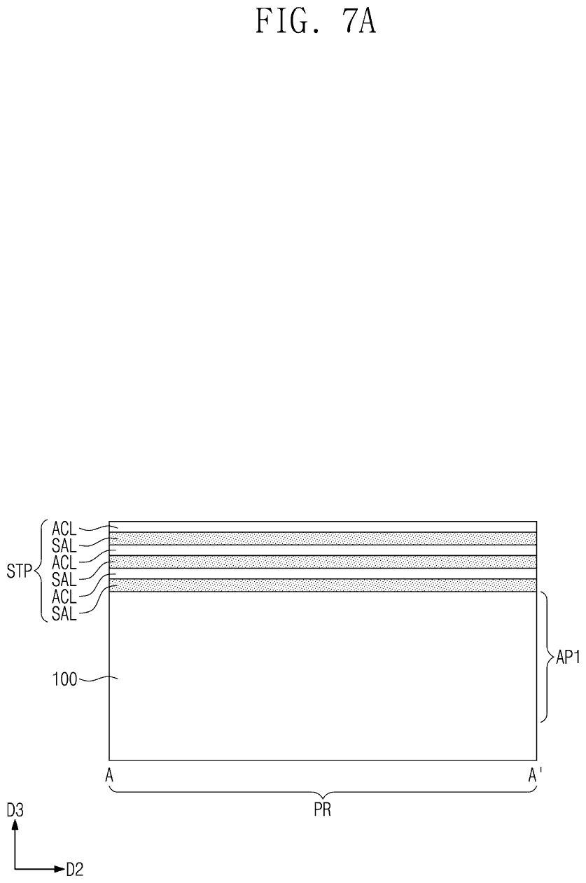

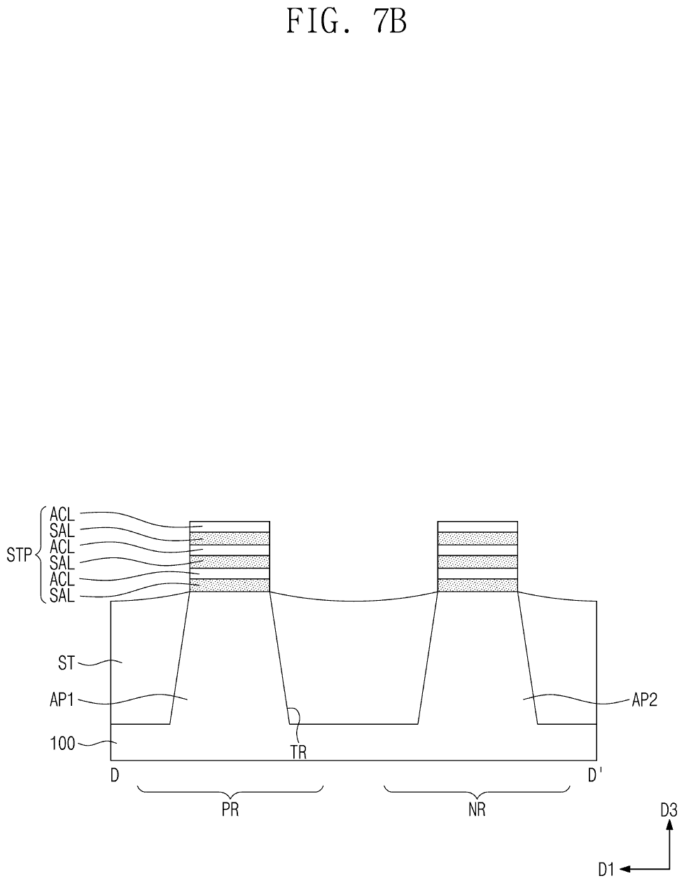

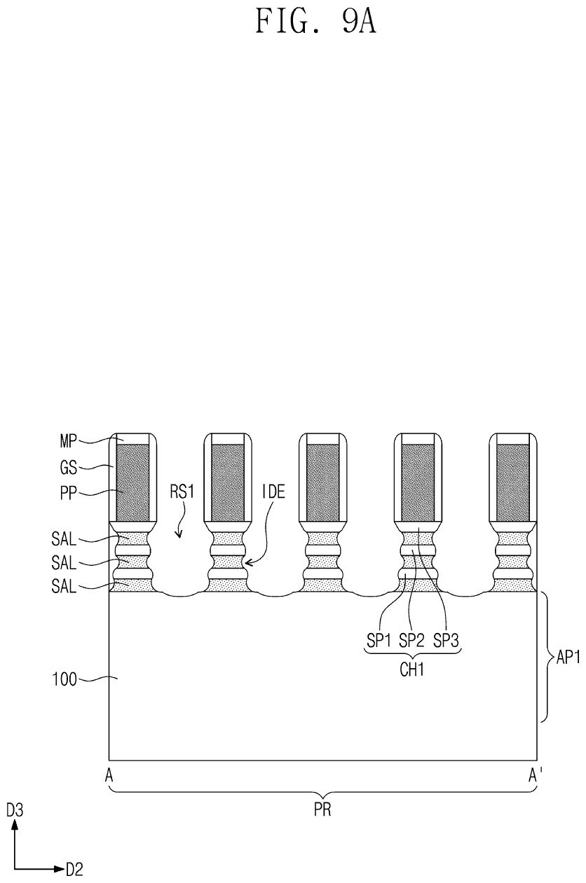

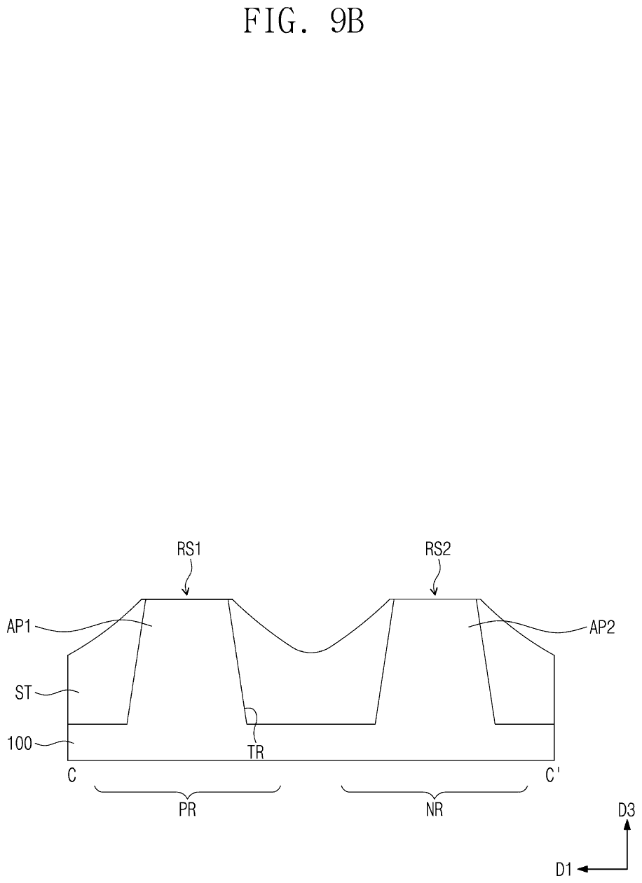

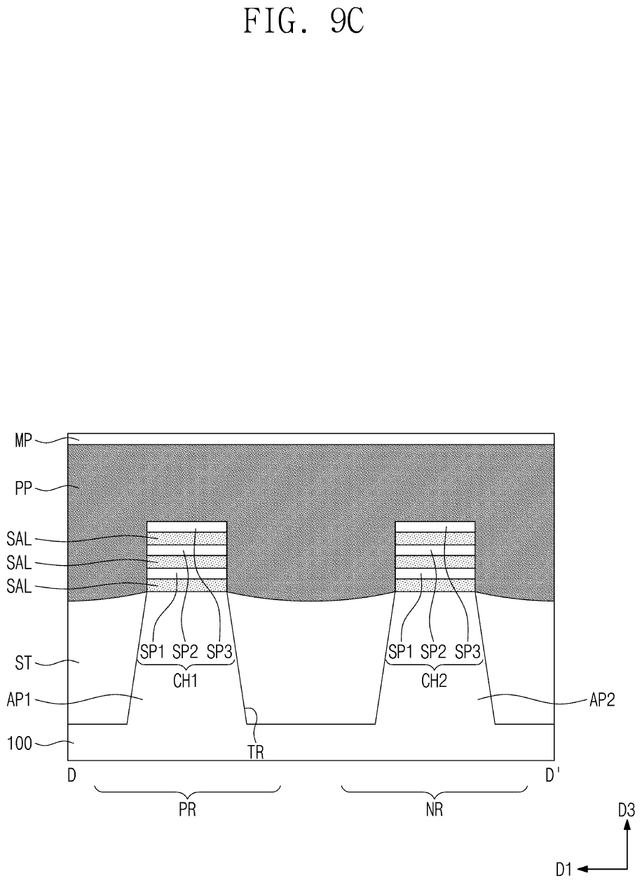

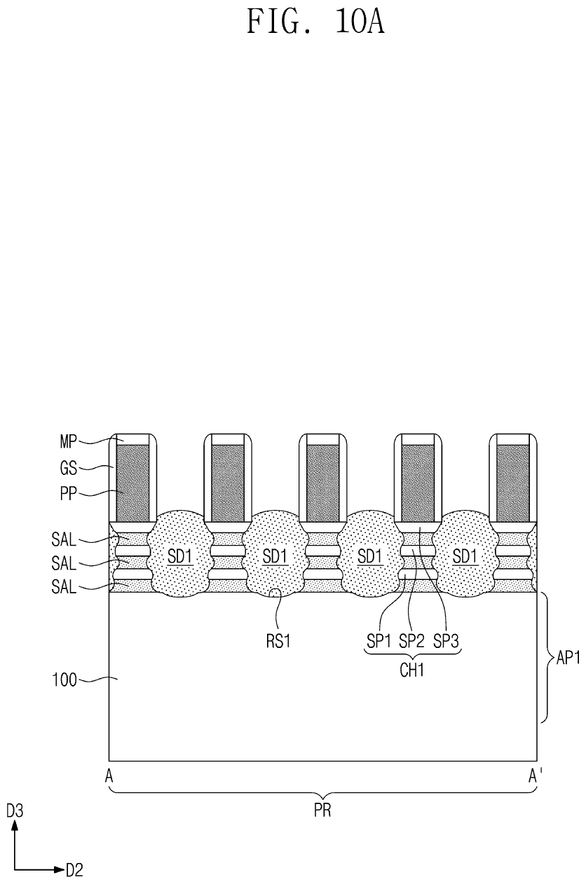

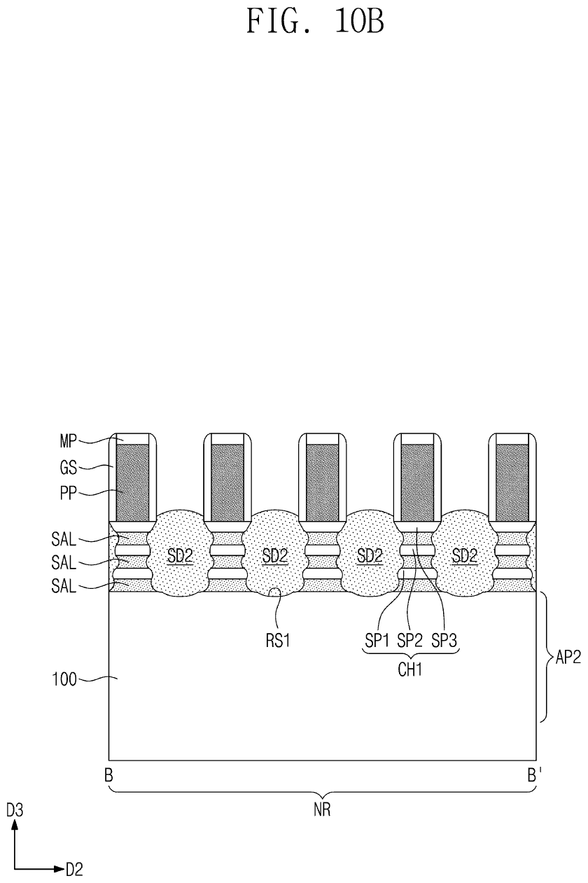

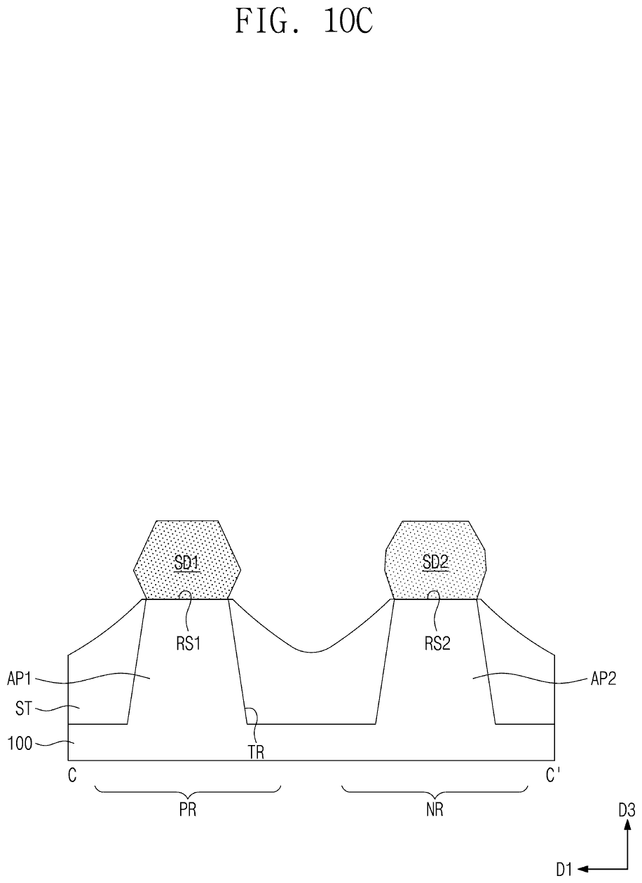

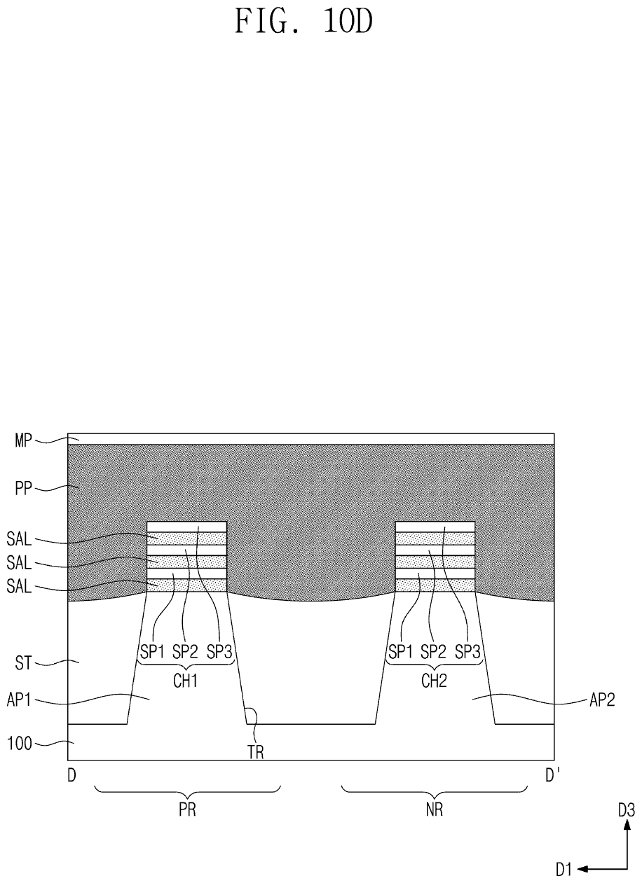

FIGS. 7A to 12C are sectional views illustrating a method of fabricating a semiconductor device, according to one or more embodiments. FIGS. 7A, 8A, 9A, 10A, 11A, and 12A are sectional views corresponding to the line A-A′ of FIG. 4. FIG. 10B is a sectional view corresponding to the line B-B′ of FIG. 4. FIGS. 9B, 10C, 11B, and 12B are sectional views corresponding to the line C-C′ of FIG. 4. FIGS. 7B, 8B, 9C, 10D, 11C, and 12C are sectional views corresponding to the line D-D′ of FIG. 4.

Referring to FIGS. 7A and 7B, the substrate 100 including the PMOSFET region PR and the NMOSFET region NR may be provided. Active layers ACL and sacrificial layers SAL may be alternately stacked on the substrate 100. The active layers ACL and the sacrificial layers SAL may be formed of or include at least one of silicon (Si), germanium (Ge), and silicon-germanium (SiGe), and here, the active layers ACL and the sacrificial layers SAL may be formed of different materials from each other.

The sacrificial layer SAL may be formed of or include at least one of materials having an etch selectivity with respect to the active layer ACL. For example, the active layers ACL may be formed of or include silicon (Si), and the sacrificial layers SAL may be formed of or include silicon germanium (SiGe). A germanium concentration of each of the sacrificial layers SAL may range from 10 at % to 30 at %.

Mask patterns may be respectively formed on the PMOSFET region PR and the NMOSFET region NR of the substrate 100. The mask pattern may be a line- or bar-shaped pattern that is extended in the second direction D2.

A patterning process using the mask patterns as an etch mask may be performed to form the trench TR defining the first active pattern AP1 and the second active pattern AP2. The first active pattern AP1 may be formed on the PMOSFET region PR. The second active pattern AP2 may be formed on the NMOSFET region NR.

A stacking pattern STP may be formed on each of the first active pattern AP1 and the second active pattern AP2. The stacking pattern STP may include the active layers ACL and the sacrificial layers SAL which are alternately stacked. The stacking pattern STP may be formed along with the first active pattern AP1 and the second active pattern AP2, during the patterning process.

The device isolation layer ST may be formed to fill the trench TR. An insulating layer may be formed on the substrate 100 to cover the first active pattern AP1 and the second active pattern AP2 and the stacking patterns STP. The device isolation layer ST may be formed by recessing the insulating layer until the stacking patterns STP are exposed. The device isolation layer ST may be formed of or include at least one of insulating materials (e.g., silicon oxide). The stacking patterns STP may be placed at a level higher than the device isolation layer ST and may be exposed to the outside of the device isolation layer ST. For example, the stacking patterns STP may protrude vertically above the device isolation layer ST.

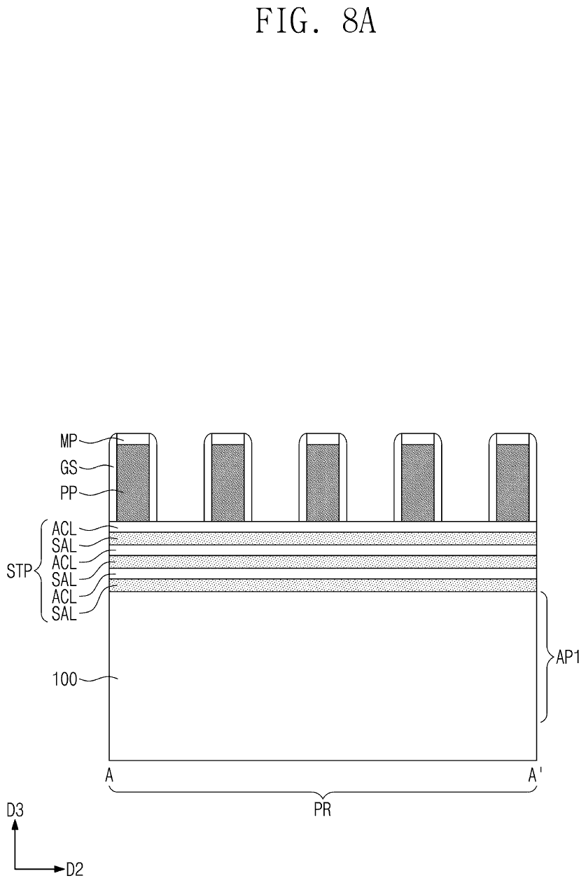

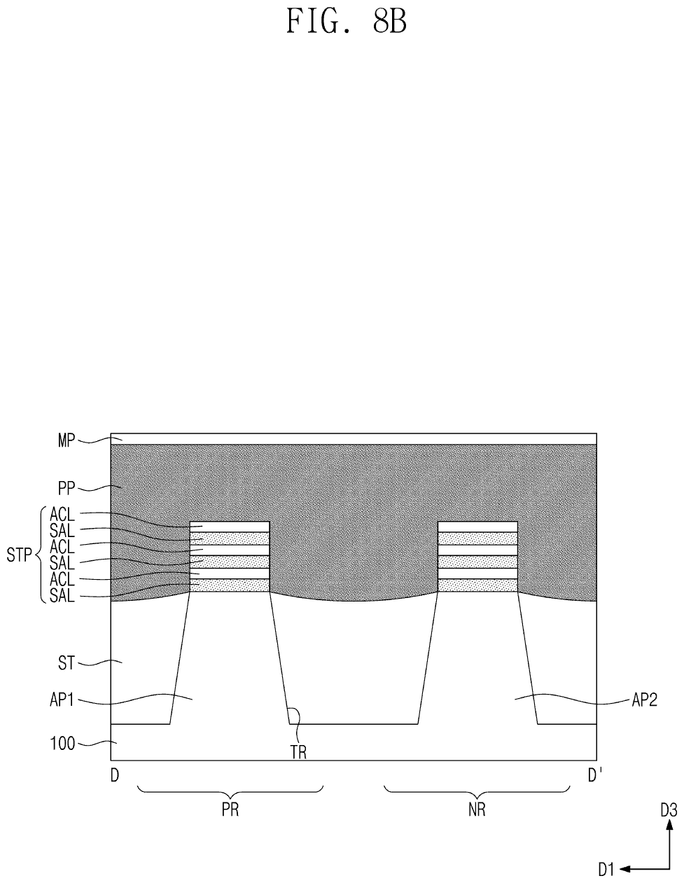

Referring to FIGS. 8A and 8B, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

The formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. In one or more embodiments, the gate spacer GS may be a multi-layered structure including at least two layers.

Referring to FIGS. 9A to 9C, the first recesses RS1 may be formed in the stacking pattern STP on the first active pattern AP1. The second recesses RS2 may be formed in the stacking pattern STP on the second active pattern AP2. During the formation of the first recesses RS1 and the second recesses RS2, the device isolation layer ST may also be recessed at both sides of each of the first active pattern AP1 and the second active pattern AP2 (e.g., see FIG. 9B).

The first recesses RS1 may be formed by etching the stacking pattern STP on the first active pattern AP1 using the hard mask patterns MP and the gate spacers GS as an etch mask. A first recess RS1 may be formed between a pair of the sacrificial patterns PP. The formation of the first recess RS1 may include additionally performing a selective etching process on exposed portions of the sacrificial layers SAL. Each of the sacrificial layers SAL may be indented by the selective etching process to form an indent region IDE. Accordingly, the first recess RS1 may be formed to have an inner side surface of a wavy shape. The second recesses RS2 in the stacking pattern STP on the second active pattern AP2 may be formed by the same method as that for the first recesses RS1.

The first to third semiconductor patterns SP1, SP2, and SP3, which are sequentially stacked on a region between adjacent ones of the first recesses RS1, may be formed from the active layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

Referring to FIGS. 10A to 10D, the first source/drain patterns SD1 may be formed in the first recesses RS1, respectively. An SEG process, in which an inner surface of the first recess RS1 is used as a seed layer, may be performed to form an epitaxial layer filling the first recess RS1. The epitaxial layer may be grown using the first to third semiconductor patterns SP1, SP2, and SP3 and the substrate 100, which are exposed by the first recess RS1, as the seed layer. In one or more embodiments, the SEG process may include a chemical vapor deposition (CVD) process and/or a molecular beam epitaxy (MBE) process.

In one or more embodiments, the first source/drain pattern SD1 may be formed of or include a semiconductor material (e.g., SiGe) whose lattice constant is greater than that of a semiconductor material of the substrate 100. During the formation of the first source/drain pattern SD1, the first source/drain pattern SD1 may be doped in-situ with p-type impurities (e.g., boron, gallium, or indium). Alternatively or additionally, impurities may be injected into the first source/drain pattern SD1, after the formation of the first source/drain pattern SD1.

The second source/drain patterns SD2 may be formed in the second recesses RS2, respectively. The second source/drain pattern SD2 may be formed by the SEG process using an inner surface of the second recess RS2 as a seed layer.

In one or more embodiments, the second source/drain pattern SD2 may be formed of or include the same semiconductor element (e.g., Si) as the substrate 100. During the formation of the second source/drain pattern SD2, the second source/drain pattern SD2 may be doped in-situ with n-type impurities (e.g., phosphorus, arsenic, or antimony). Alternatively or additionally, impurities may be injected into the second source/drain pattern SD2, after the formation of the second source/drain pattern SD2.

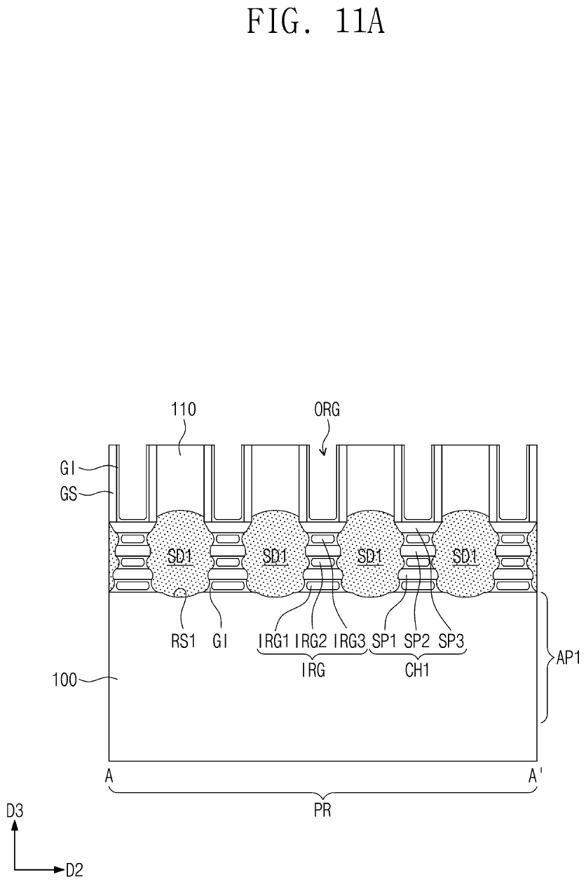

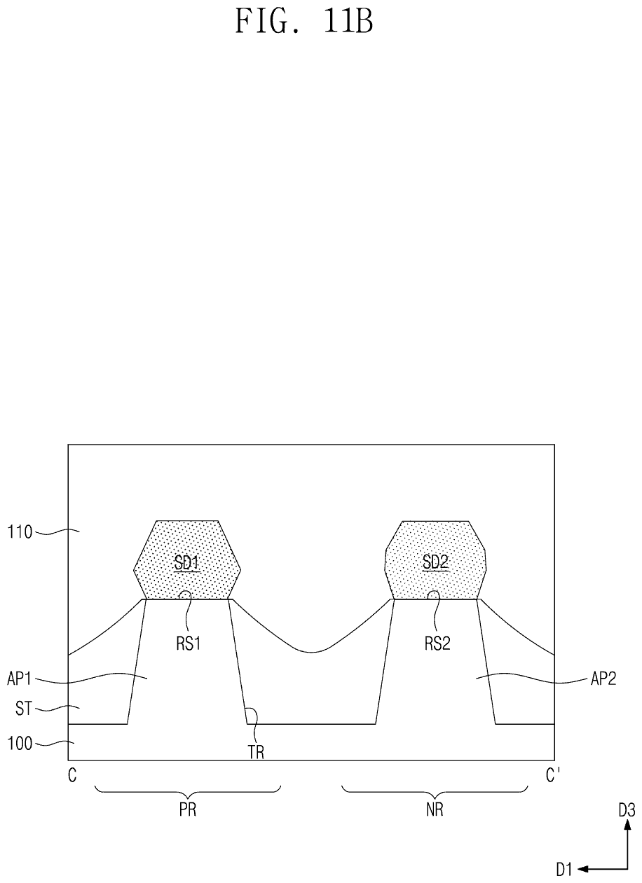

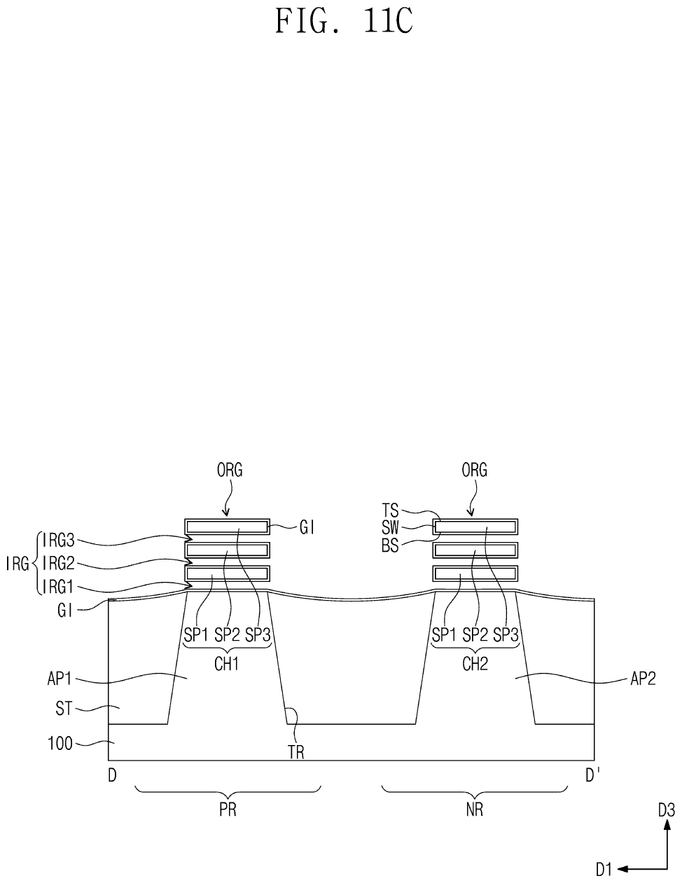

Referring to FIGS. 11A to 11C, the first interlayer insulating layer 110 may be formed on the first source/drain patterns SD1 and the second source/drain patterns SD2, the hard mask patterns MP, and the gate spacers GS. In one or more embodiments, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the hard mask patterns MP may be removed during the planarization process. As a result, the first interlayer insulating layer 110 may be formed to have a top surface that is coplanar with the top surfaces of the sacrificial patterns PP and the top surfaces of the gate spacers GS.

In one or more embodiments, the exposed sacrificial patterns PP may be selectively removed. As a result of the removal of the sacrificial patterns PP, an outer region ORG exposing the first channel pattern CH1 and the second channel pattern CH2 may be formed (e.g., see FIG. 11C). The removal of the sacrificial patterns PP may include a wet etching process which is performed using an etching solution capable of selectively etching polysilicon.

The sacrificial layers SAL, which are exposed through the outer region ORG, may be selectively removed to form inner regions IRG (e.g., see FIG. 11C). A process of selectively etching the sacrificial layers SAL may be performed to leave the first to third semiconductor patterns SP1, SP2, and SP3 and to remove only the sacrificial layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the sacrificial layers SAL on the PMOSFET region PR and the NMOSFET region NR may be removed. The etching process may be a wet etching process. An etchant material, which is used in the etching process, may be chosen to quickly remove the sacrificial layer SAL having a relatively high germanium concentration.

Referring back to FIG. 11C, since the sacrificial layers SAL are selectively removed, only the first to third semiconductor patterns SP1, SP2, and SP3, which are stacked on each of the first active pattern AP1 and the second active pattern AP2, may be left. Empty regions, which are formed by removing the sacrificial layers SAL, may form first to third inner regions IRG1, IRG2, and IRG3, respectively.

The first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11C, the gate insulating layer GI may be formed on exposed surfaces of the first to third semiconductor patterns SP1, SP2, and SP3. The gate insulating layer GI may be formed to surround each of the first to third semiconductor patterns SP1, SP2, and SP3. The gate insulating layer GI may be formed in each of the first to third inner regions IRG1, IRG2, and IRG3. The gate insulating layer GI may be formed in the outer region ORG.

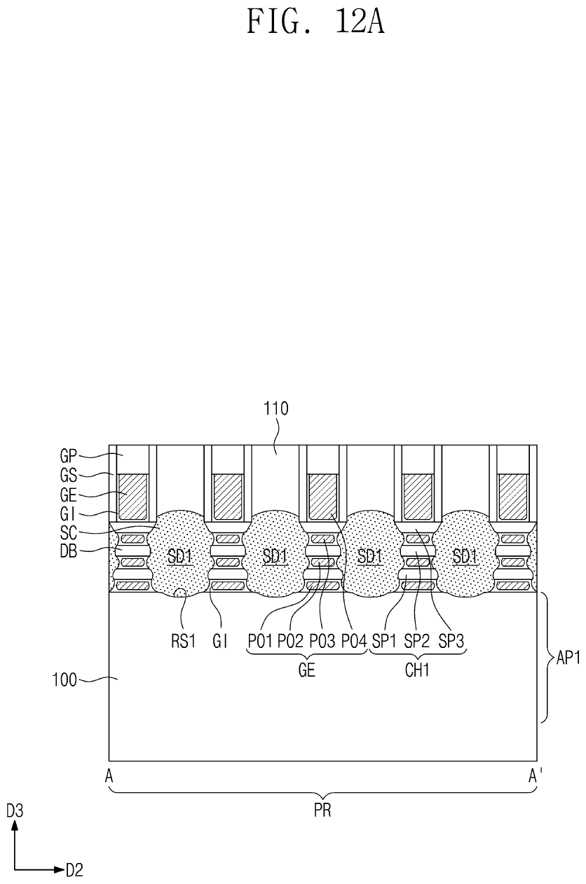

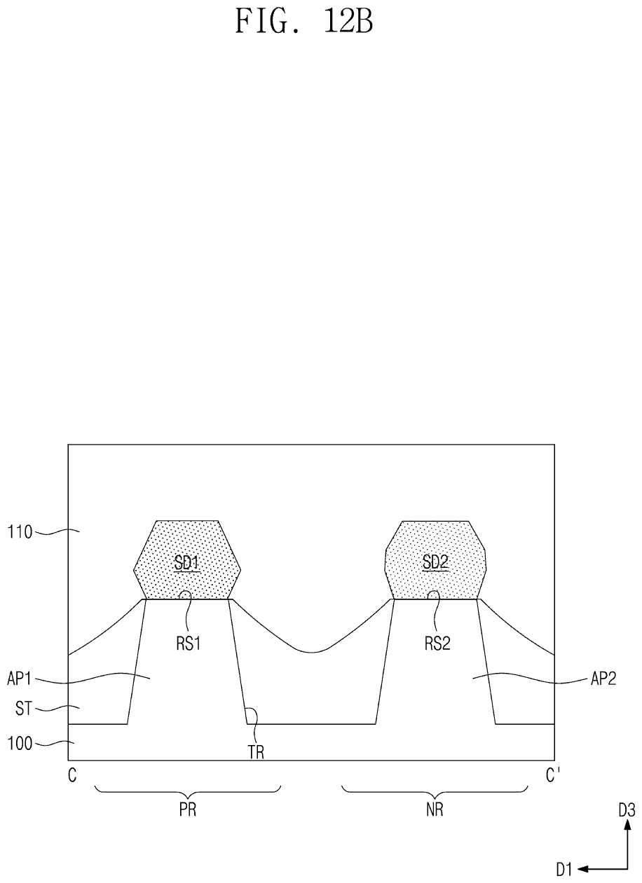

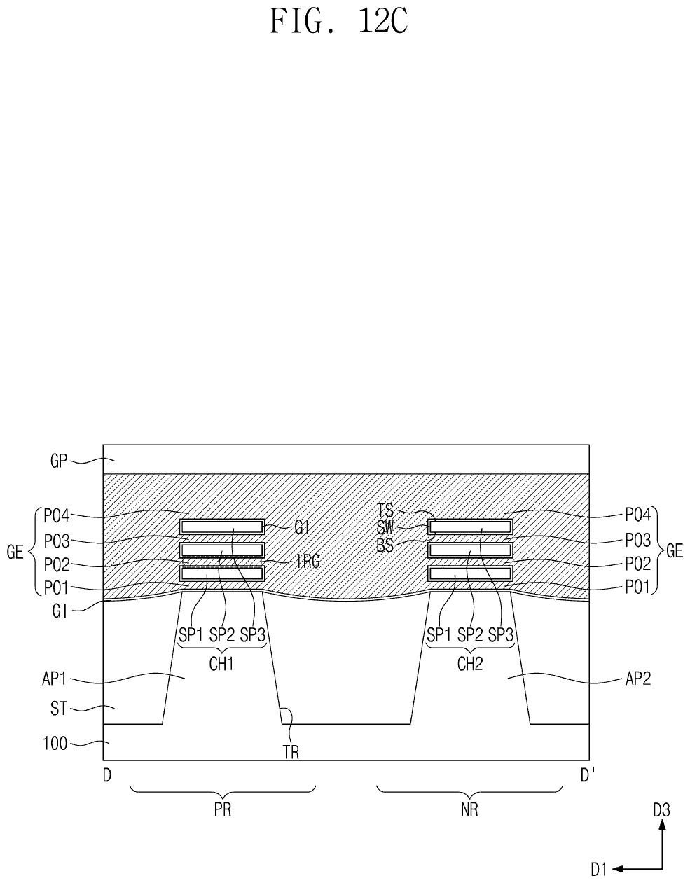

Referring to FIGS. 12A to 12C, the gate electrode GE may be formed on the gate insulating layer GI. The gate electrode GE may include the first portion PO1 and the second portion PO2, which are formed in the first inner region IRG1 and the second inner region IRG2, respectively, and the third portion PO3, which is formed in the outer region ORG. The gate electrode GE may be vertically recessed to have a reduced height. The gate capping pattern GP may be formed on the recessed gate electrode GE.

Referring back to FIGS. 5A to 5D, the second interlayer insulating layer 120 may be formed on the first interlayer insulating layer 110. The second interlayer insulating layer 120 may include a silicon oxide layer. The first active contact AC1 and the second active contact AC2 may be formed to penetrate the second interlayer insulating layer 120 and the first interlayer insulating layer 110 and may be electrically connected to the first source/drain patterns SD1 and the second source/drain patterns SD2. The gate contact GC may be formed to penetrate the second interlayer insulating layer 120 and the gate capping pattern GP and may be electrically connected to the gate electrode GE.

The formation of each of the active and gate contacts AC and GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

The division structures DB may be respectively formed on the first border BD1 and the second border BD2 of the single height cell SHC. The division structure DB may penetrate the second interlayer insulating layer 120 and the gate electrode GE and may be extended into the active pattern AP1 or AP2. The division structure DB may include an insulating material (e.g., silicon oxide or silicon nitride).

The third interlayer insulating layer 130 may be formed on the active contacts AC and the gate contacts GC. The third interlayer insulating layer 130 may include tetraethyl orthosilicate (TEOS). The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

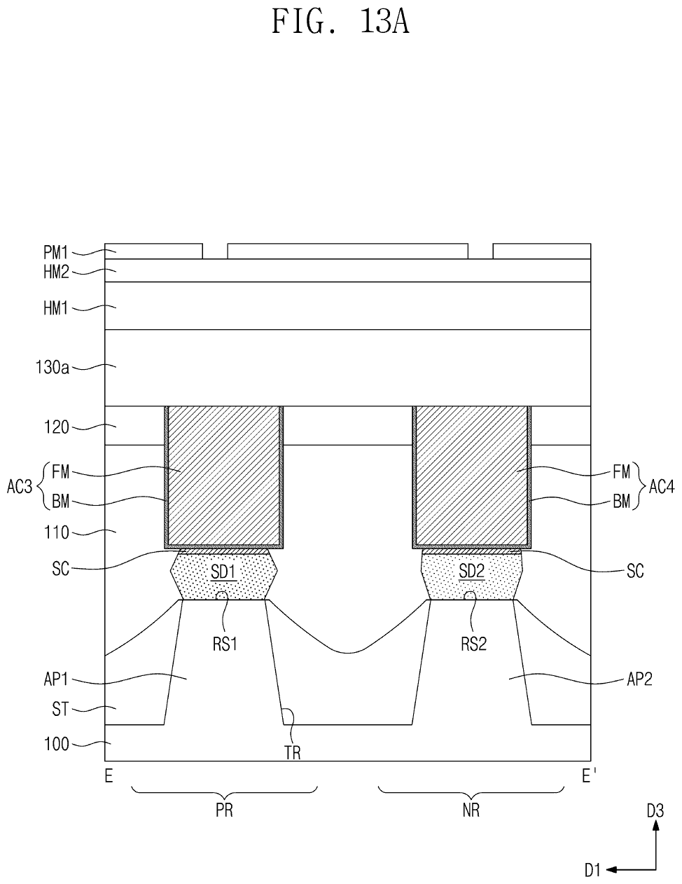

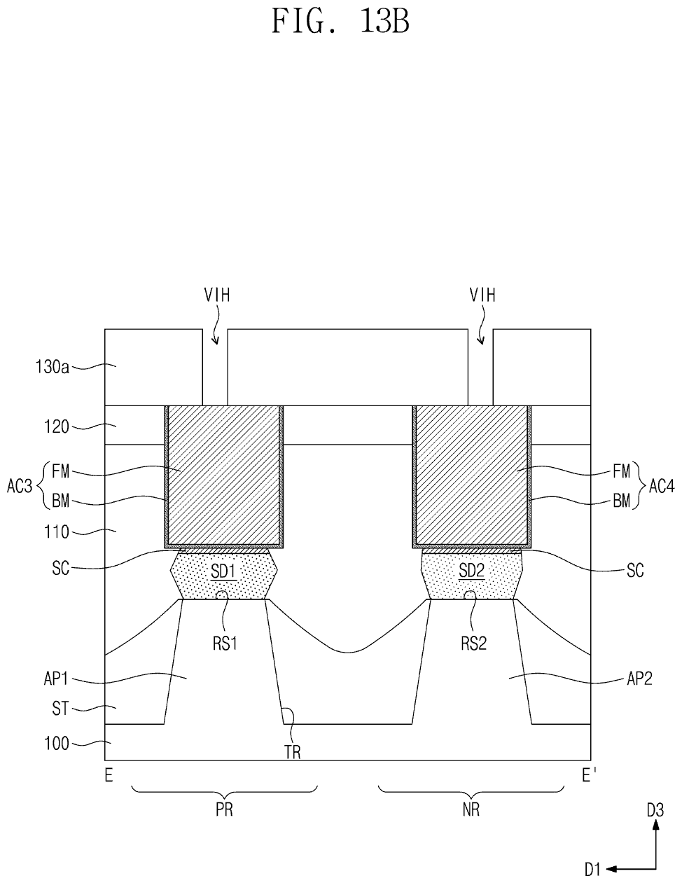

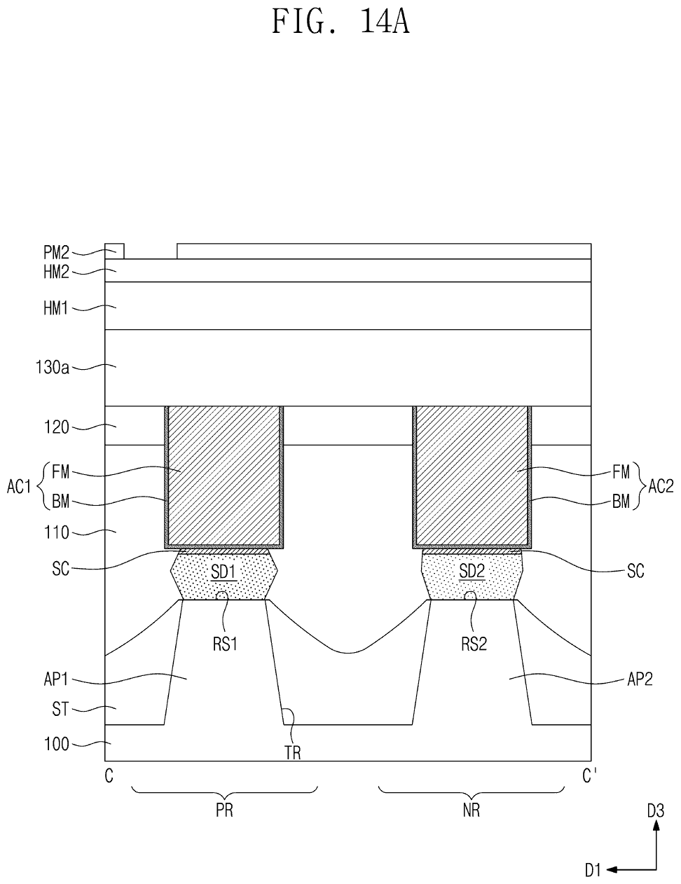

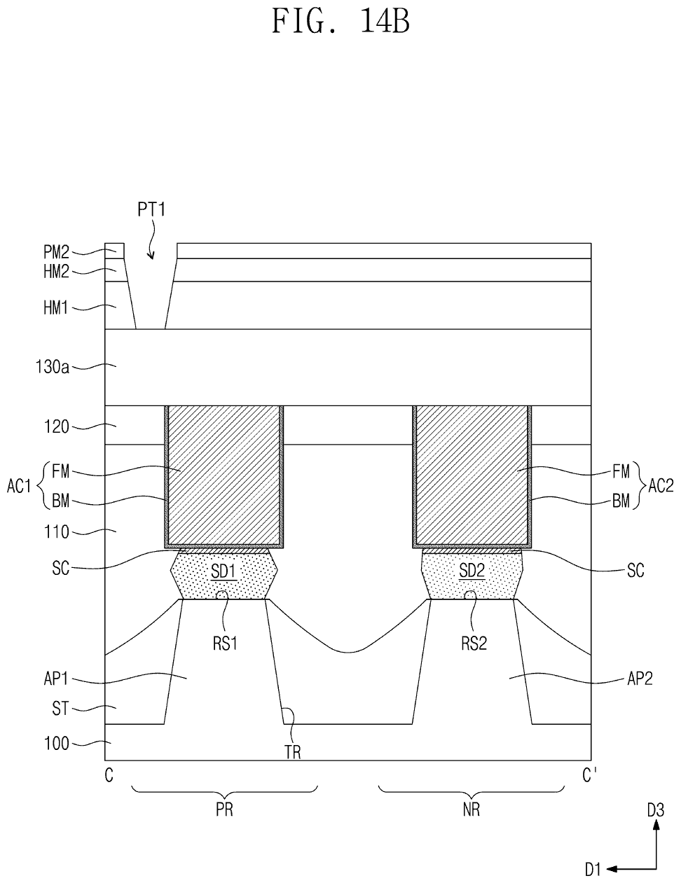

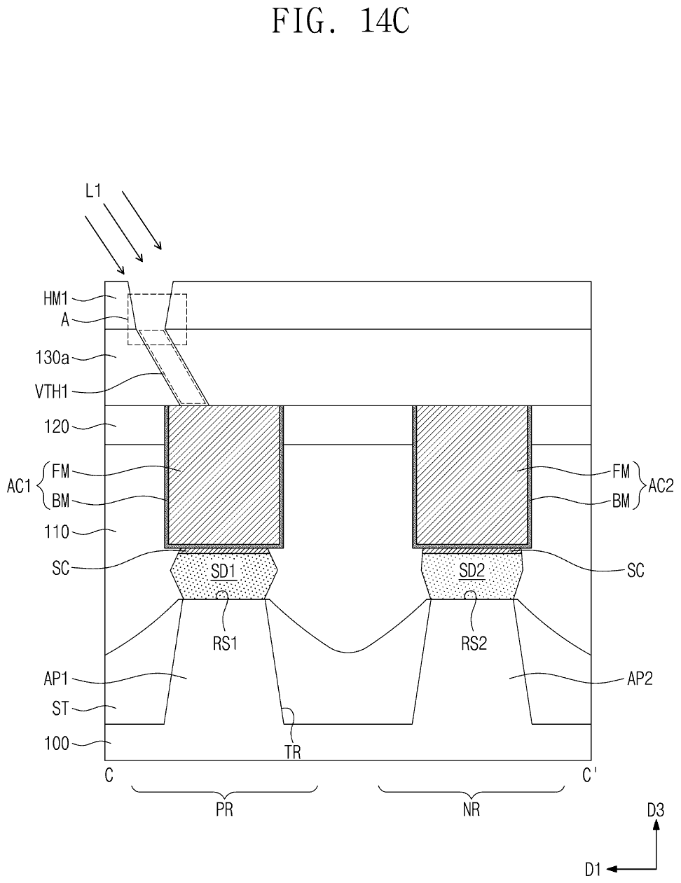

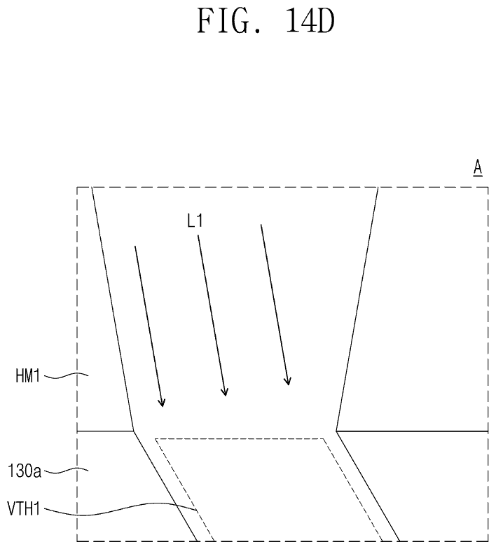

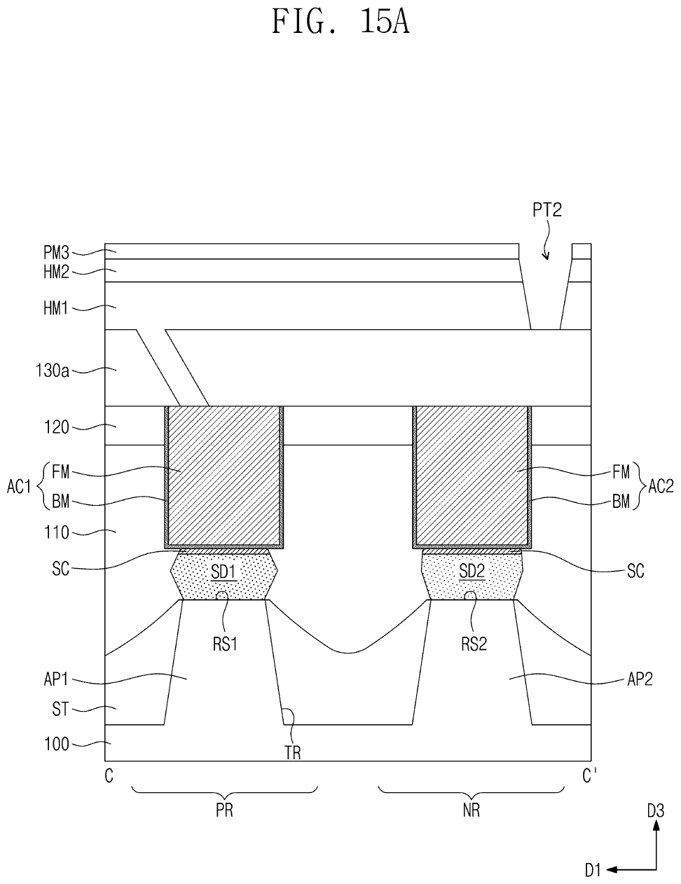

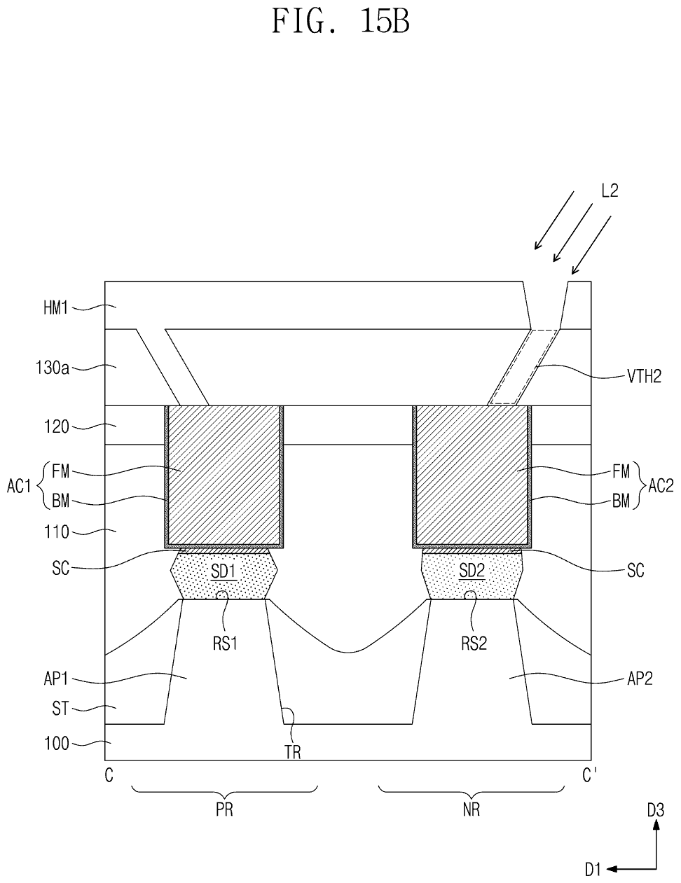

FIGS. 13A and 13B are sectional views illustrating a method of fabricating the semiconductor device of FIG. 5E. FIGS. 14A to 15C are sectional views illustrating a method of fabricating the semiconductor device of FIG. 5C. FIGS. 13A and 13B are sectional views corresponding to the line E-E′ of FIG. 4. FIGS. 14A to 15C are sectional views corresponding to the line C-C′ of FIG. 4. FIG. 14D is an enlarged view illustrating a portion ‘A’ of FIG. 14C. The method of forming the first metal layer M1 will be described in more detail with reference to FIGS. 13A and 15C.

Referring to FIG. 13A, a first hard mask HM1 and a second hard mask HM2 may be sequentially formed on a first preliminary interlayer insulating layer 130a. The first hard mask HM1 may include an insulating material. For example, the first hard mask HM1 may be a spin-on-hardmask (SOH). The second hard mask HM2 may include an insulating material. For example, the second hard mask HM2 may be formed of or include at least one of SiON, SiCN, SiCON, and SiN.

A first photoresist pattern PM1 may be formed on the second hard mask HM2. The first photoresist pattern PM1 may include a material having a different etch rate from the first preliminary interlayer insulating layer 130a.

Referring to FIG. 13B, an etching process using the first photoresist pattern PM1 as a mask may be performed to partially etch the first hard mask HM1 and the second hard mask HM2. An etching process using the etched first hard mask HM1 and the second hard mask HM2 as a mask may be performed to form via holes VIH in the first preliminary interlayer insulating layer 130a. The via holes VIH may be formed to expose top surfaces of the third and fourth active contacts AC3 and AC4. The via holes VIH, along with via contact holes VTH to be described below, may be filled with a metallic material.

Referring to FIG. 14A, the first hard mask HM1 and the second hard mask HM2 may be sequentially formed on the first preliminary interlayer insulating layer 130a. The first hard mask HM1 may include an insulating material. For example, the first hard mask HM1 may be a spin-on-hardmask (SOH). The second hard mask HM2 may include an insulating material. For example, the second hard mask HM2 may be formed of or include at least one of SiON, SiCN, SiCON, or SiN.

A second photoresist pattern PM2 may be formed on the second hard mask HM2. The second photoresist pattern PM2 may include a material having a different etch rate from that of the first preliminary interlayer insulating layer 130a.

Referring to FIG. 14B, a first patterning hole PT1 may be formed by partially etching the first hard mask HM1 and the second hard mask HM2 through an etching process using the second photoresist pattern PM2 as a mask. The first patterning hole PT1 may be formed to expose a top surface of the first preliminary interlayer insulating layer 130a. A width of the first patterning hole PT1 in the first direction D1 may decreases as a distance from the top surface of the first preliminary interlayer insulating layer 130a in the vertical direction D3 decreases. Alternatively, the width of the first patterning hole PT1 in the first direction D1 may be substantially constant, regardless of the position in the vertical direction D3.

Referring to FIG. 14C, the second photoresist pattern PM2 and the second hard mask HM2 may be removed. The first preliminary interlayer insulating layer 130a may be etched by performing an etching process using the first hard mask HM1 as a mask. The etching process may be an ion beam etching (IBE) process. An irradiation beam L1 including energetic ions may be incident into the first hard mask HM1 at a specific incident angle. The incident angle of the irradiation beam L1, which is an angle between the irradiation beam L1 and the first direction D1, may be acute. The substrate 100 may be tilted to realize the incident angle of the irradiation beam L1.

Referring to FIG. 14D, a first via contact hole VTH1 may be formed in the first preliminary interlayer insulating layer 130a by the irradiation beam L1. Due to the tilted incidence of the irradiation beam L1, the first via contact hole VTH1 may be formed to be inclined at an angle to both of the vertical direction D3 and the first direction D1. The first via contact hole VTH1 may be formed to expose the top surface of the first active contact AC1.

An inner side surface of the first via contact hole VTH1 may include a first inner side surface and a second inner side surface, which are opposite to each other in the first direction D1. The first inner side surface may be inclined at an acute angle to the exposed top surface of the first active contact AC1. The second inner side surface may be inclined at an obtuse angle to the exposed top surface of the first active contact AC1.

Referring to FIG. 15A, the first hard mask HM1 and the second hard mask HM2 may be sequentially formed on the first preliminary interlayer insulating layer 130a. The first hard mask HM1 and the second hard mask HM2 may be formed to have substantially the same features as those of the first hard mask HM1 and the second hard mask HM2 previously described with reference to FIG. 14A.

A third photoresist pattern PM3 may be formed on the second hard mask HM2. An etching process using the third photoresist pattern PM3 as a mask may be performed to partially etch the first hard mask HM1 and the second hard mask HM2 and to form a second patterning hole PT2. The second patterning hole PT2 may be formed by substantially the same method as that for the first patterning hole PT1 described with reference to FIG. 14B.

Referring to FIG. 15B, the third photoresist pattern PM3 and the second hard mask HM2 may be removed. A second via contact hole VTH2 may be formed in the first preliminary interlayer insulating layer 130a by performing an etching process using the first hard mask HM1 as a mask. The second via contact hole VTH2 may be formed by substantially the same method as that for the first via contact hole VTH1 described with reference to FIGS. 14C and 14D. However, an incident angle of an irradiation beam L2, which is an angle between the irradiation beam L2 and the first direction D1, may be obtuse. The second via contact hole VTH2 may be formed to expose the top surface of the second active contact AC2.

Referring to FIGS. 15C and 5C, the first hard mask HM1 may be selectively removed. The first via contact VT1 and the second via contact VT2 may be formed by filling the first via contact hole VTH1 and the second via contact hole VTH2 with a metallic material. The formation of the first via contact VT1 and the second via contact VT2 may include forming the via barrier pattern VBM in the first via contact hole VTH1 and the second via contact hole VTH2 and forming the via conductive pattern VFM on the via barrier pattern VBM.

The third interlayer insulating layer 130 may be formed by forming a second preliminary interlayer insulating layer 130b on the first preliminary interlayer insulating layer 130a. The first power line M1_R1, the second power line M1_R2, and the first single interconnection lines M1_I may be formed in the second preliminary interlayer insulating layer 130b.

In the fabrication method according to one or more embodiments, since the via contact is formed to have a tilted shape, all of the active contacts may be formed to have the same width. Thus, it may be possible to simplify a process of forming the active contacts.

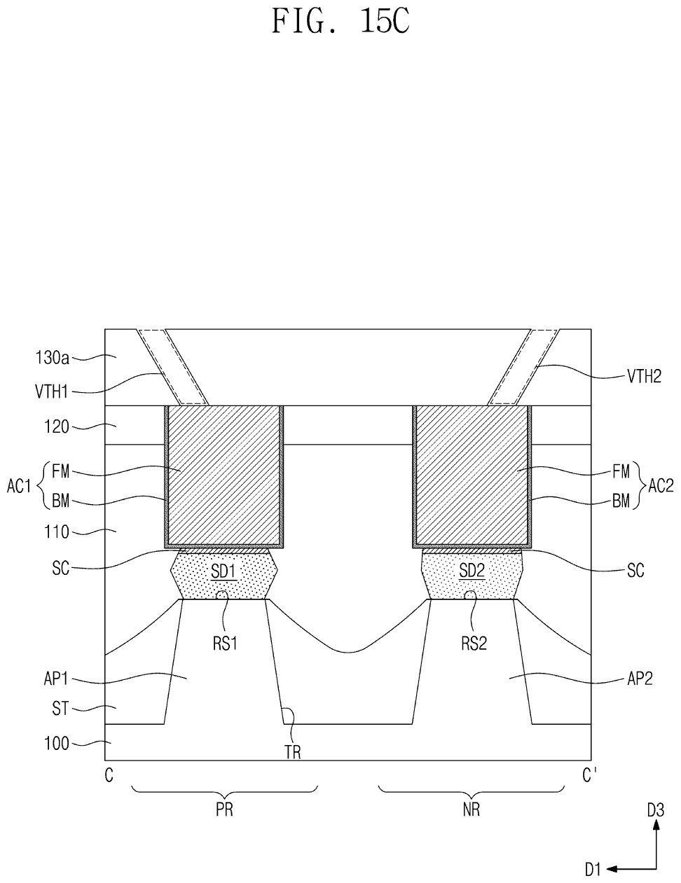

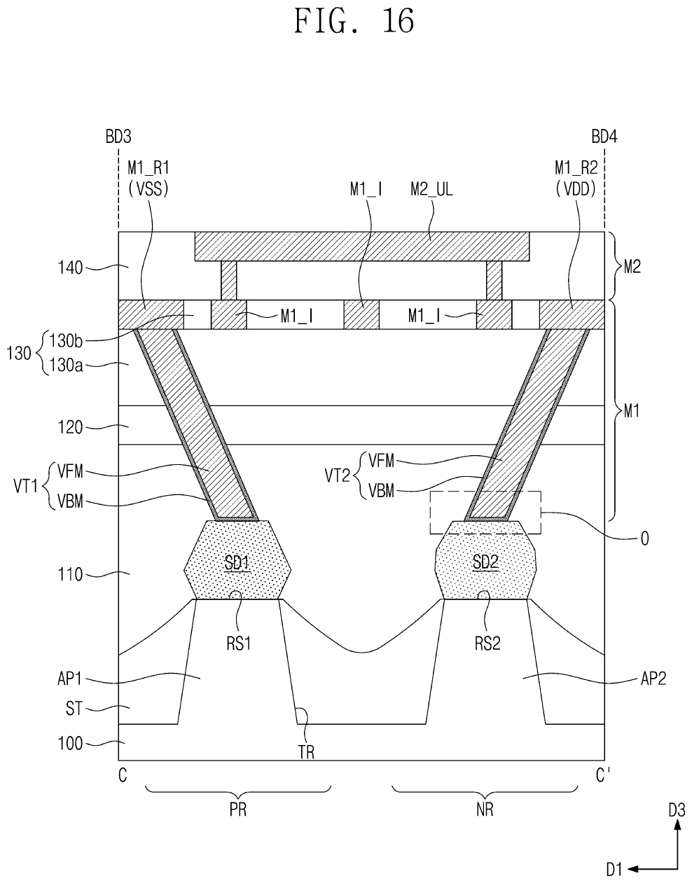

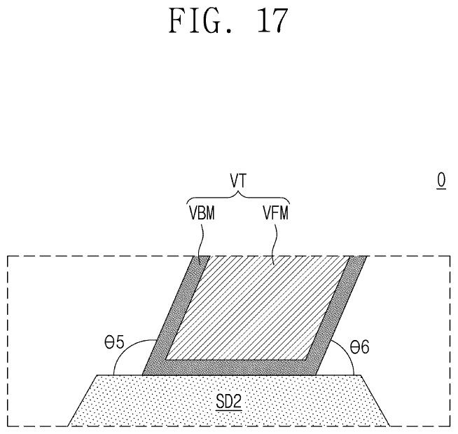

Hereinafter, another embodiment will be described in more detail. In the following description, an element previously described with reference to FIGS. 1 to 6B may be identified by the same reference number without repeating an overlapping description thereof. FIG. 16 is a sectional view, which is taken along a line C-C′ of FIG. 4 to illustrate a semiconductor device according to one or more embodiments. FIG. 17 is an enlarged sectional view illustrating a portion ‘O’ of FIG. 16.

Referring to FIGS. 16 and 17, the first active contact AC1 and the second active contact AC2 on the first source/drain pattern SD1 and the second source/drain pattern SD2 may be omitted. The first via contact VT1 may electrically connect the first source/drain pattern SD1 to the first power line M1_R1. The second via contact VT2 may electrically connect the second source/drain pattern SD2 to the second power line M1_R2. A bottom surface of the first via contact VT1 may be in direct contact with a top surface of the first source/drain pattern SD1. A bottom surface of the second via contact VT2 may be in direct contact with a top surface of the second source/drain pattern SD2.

For example, the second via contact VT2 may include a first side surface and a second side surface. The first side surface and the second side surface may be opposite to each other in the first direction D1. The top surface of the first source/drain pattern SD1 may be parallel to the first direction D1. The first side surface may be inclined at a fifth angle θ5 to the top surface of the first source/drain pattern SD1. The second side surface may be inclined at a sixth angle θ6 to the top surface of the first source/drain pattern SD1. The fifth angle θ5 may be an obtuse angle, and the sixth angle θ6 may be an acute angle. For example, the fifth angle θ5 may range from 100° to 150°. The sixth angle θ6 may range from 30° to 80°. The first via contact VT1 may be provided to have substantially the same features as the second via contact VT1.

In the present embodiment, the first active contact AC1 and the second active contact AC2 may not be provided, and the first source/drain pattern SD1 and the second source/drain pattern SD2 may be directly connected to the first power line M1_R1 and the second power line M1_R2 through the first via contact VT1 and the second via contact VT2. Thus, it may be possible to reduce the cost required to form the first active contact AC1 and the second active contact AC2.

According to one or more embodiments, a semiconductor device may include a via contact connecting an active contact to a power line. The via contact may be formed to be tilted from a top surface of the active contact. The via contacts may be formed by etching a tilted substrate with an ion beam. Since the via contact directly connects the active contact to the power line, the active contacts may not need to have a large length. For example, the active contacts may be formed to have the same length, and this may make it possible to simplify the fabrication process. In addition, it may be possible to prevent the active contact, which has a large length, from being in contact with a side surface of a source/drain pattern. As a result, the electrical characteristics of the semiconductor device may be improved.

In the above embodiments, a tilted via contact is described as connecting a source/drain pattern to a power line. However, the disclosure may not be limited thereto. For example, a tilted via contact may be formed to directly or indirectly connect the source/drain pattern to a metal line providing the source/drain region with a connection with another circuit element for internal routing purposes depending of a design of a cell or circuit in a semiconductor device.

While example embodiments have been particularly shown and described, it will be understood by one of ordinary skill in the art that variations in form and detail may be made therein without departing from the spirit and scope of the attached claims.

What is claimed is:

1. A semiconductor device, comprising:
a first source/drain pattern;
a first active contact on the first source/drain pattern;
a power line above the first active contact; and
a first via contact connecting the first active contact to the power line,
wherein the first via contact comprises a first side surface and a second side surface, which are opposite to each other in a first direction,
wherein the first side surface is inclined at a first angle to a top surface of the first active contact,
wherein the second side surface is inclined at a second angle to the top surface of the first active contact, and
wherein the first angle is an obtuse angle, and the second angle is an acute angle.

2. The semiconductor device of claim 1, wherein the first angle ranges from 100° to 150°.

3. The semiconductor device of claim 1, wherein the second angle ranges from 30° to 80°.

4. The semiconductor device of claim 1, wherein a vertical center line of a top surface of the first via contact is offset from a vertical center line of a bottom surface of the first via contact in the first direction.

5. The semiconductor device of claim 1, further comprising:
a second source/drain pattern spaced apart from the first source/drain pattern in a second direction, the second direction intersecting the first direction;
a second active contact on the second source/drain pattern;
an interconnection line above the second active contact; and
a second via contact vertically connecting the second active contact to the interconnection line.

6. The semiconductor device of claim 5, wherein a width of the first active contact in the first direction is equal to a width of the second active contact in the first direction.

7. The semiconductor device of claim 1, wherein the power line is a conductive line, to which a drain voltage or a source voltage is provided.

8. The semiconductor device of claim 1, wherein the first via contact comprises a via conductive pattern and a via barrier pattern enclosing the via conductive pattern, and
wherein the via barrier pattern is in direct contact with the top surface of the first active contact.

9. The semiconductor device of claim 1, wherein a top surface of the first via contact is in contact with a bottom surface of the power line, and
wherein a bottom surface of the first via contact is in contact with the top surface of the first active contact.

10. A semiconductor device, comprising:
a first source/drain pattern and a second source/drain pattern;
a first active contact on the first source/drain pattern and a second active contact on the second source/drain pattern;
a first power line and a second power line spaced apart from each other in a first direction;
a first via contact connecting the first active contact to the first power line and comprising a first side surface; and
a second via contact connecting the second active contact to the second power line and comprising a second side surface,
wherein the first side surface has a first slope, and the second side surface has a second slope, and
wherein one of the first slope and the second slope is a positive slope, and the other is a negative slope.

11. The semiconductor device of claim 10, wherein a distance between the first and second side surfaces increases as a distance from a top surface of the substrate in a vertical direction increases.

12. The semiconductor device of claim 10, wherein one of the first source/drain pattern and the second source/drain pattern comprises a p-type impurity, and the other comprises an n-type impurity.

13. The semiconductor device of claim 10, wherein the first side surface is inclined at a first angle to a top surface of the first active contact,
wherein the second side surface is inclined at a second angle to a top surface of the second active contact, and
wherein the first angle and the second angle ranges from 100° to 150°.

14. The semiconductor device of claim 10, wherein one of the first power line and the second power line is a drain voltage line, and the other is a source voltage line.

15. The semiconductor device of claim 10, wherein the first side surface and the second side surface are opposite to each other in the first direction.

16. A semiconductor device, comprising:
a first source/drain pattern and a second source/drain pattern on a substrate;
a channel pattern connected to the first source/drain pattern and the second source/drain pattern, the channel pattern comprising a plurality of semiconductor patterns, which are stacked to be spaced apart from each other;
a first active contact and a second active contact coupled to the first source/drain pattern and the second source/drain pattern, respectively;
a first power line and a second power line spaced apart from each other in a first direction; and
a first via contact and a second via contact on bottom surfaces of the first power line and the second power line, respectively,
wherein the first via contact connects the first power line to the first active contact,
wherein the second via contact connects the second power line to the second active contact, and
wherein a distance between the first active contact and the second active contact increases as a distance from a top surface of the substrate in a vertical direction increases.

17. The semiconductor device of claim 16, wherein a vertical center line of a top surface of each of the first via contact and the second via contact is offset from a center line of a bottom surface of each of the first via contact and the second via contact in the first direction.

18. The semiconductor device of claim 16, wherein one of the first power line and the second power line is configured to provide a drain voltage, and the other is configured to provide a source voltage.

19. The semiconductor device of claim 16, wherein each of the first via contact and the second via contact comprises a via conductive pattern and a via barrier pattern enclosing the via conductive pattern, and
wherein the via barrier pattern is in contact with a top surface of each of the first active contact and the second active contact.

20. The semiconductor device of claim 16, wherein one of the first source/drain pattern and the second source/drain pattern comprises a p-type impurity, and the other comprises an n-type impurity.
